(19) United States
(12) Patent Application Publication
(10) Pub. No.: US 2016/0064175 A1
(43) Pub. Date: Mar. 3, 2016

(54) STRUCTURED TARGETS FOR X-RAY GENERATION

(71) Applicant: SINGRAY, INC, Concord, CA (US)

(72) Inventors: Wenbing YUN, Walnut Creek, CA (US); Janos KIRZ, Berkeley, CA (US); Sylvia Jia Yun LEWIS, San Francisco, CA (US)

(73) Assignee: SIGRAY, INC., Concord, CA (US)

(21) Appl. No.: 14/784,029

(22) PCT Filed: Aug. 29, 2014
(86) PCT No.: PCT/US2014/053603

§ 371 Date: Oct. 12, 2015

Related U.S. Application Data
(63) Continuation of application No. 14/465,816, filed on Aug. 21, 2014.
(60) Provisional application No. 61/873,735, filed on Sep. 4, 2013.
(60) Provisional application No. 61/880,151, filed on Sep. 19, 2013.
(60) Provisional application No. 61/894,073, filed on Oct. 22, 2013.
(60) Provisional application No. 61/931,519, filed on Jan. 24, 2014.

(51) Int. Cl. H01J 35/12; G03F 7/16; G03F 7/36; H01J 35/10

(52) U.S. Cl. CPC H01J 35/12; H01J 35/105; G03F 7/16; G03F 7/36; H01J 2235/081; H01J 2235/1204

(57) ABSTRACT

Disclosed are targets for generating x-rays using electron beams and their method of fabrication. They comprise a number of microstructures fabricated from an x-ray target material arranged in close thermal contact with a substrate such that the heat is more efficiently drawn out of the x-ray target material. This allows irradiation of the x-ray generating substance with higher electron density or higher energy electrons, leading to greater x-ray brightness, without inducing damage or melting. The microstructures may comprise conventional x-ray target materials (such as tungsten) that are patterned at micron-scale dimensions on a thermally conducting substrate, such as diamond. The microstructures may have any number of geometric shapes to best generate x-rays of high brightness and efficiently disperse heat. In some embodiments, the target comprising microstructures may be incorporated into a rotating anode geometry, to enhance x-ray generation in such systems.

### CROSS-REFERENCE TO RELATED APPLICATIONS

This patent application claims priority to and the benefit of U.S. Provisional Patent Application Nos. 61/873,735, filed on Sep. 4, 2013; 61/880,151, filed on Sep. 19, 2013; 61/894,073, filed on Oct. 22, 2013; and 61/931,519, filed on Jan. 24, 2014, all of which are incorporated herein by reference in their entirety. This application also claims priority to and claims the benefit of U.S. application Ser. No. 14/465,816 filed Aug. 21, 2014, which is hereby incorporated by reference in its entirety.

### FIELD

The embodiments of the invention disclosed herein relate to specially designed targets for electron beams that can be used in high-brightness sources of x-rays. Such high brightness sources may be useful for a variety of applications in which x-rays are employed, including but not limited to manufacturing inspection, metrology, crystallography, structure analysis and medical imaging and diagnostic systems.

### BACKGROUND

The initial discovery of x-rays by Röntgen in 1895 [W. C. Röntgen, “Eine Neue Art von Strahlen (Wurzburg Verlag, 1895); “On a New Kind of Rays,” Nature, Vol. 53, pp. 274-276 (Jan. 23 1896)] occurred by accident when Röntgen was experimenting with electron bombardment of targets in vacuum tubes. These high energy, short wavelength photons are now routinely used for medical applications and diagnostic evaluations, as well as for security screening, industrial inspection, quality control and failure analysis, and for scientific applications such as crystallography, tomography, x-ray fluorescence analysis and the like.

The laboratory x-ray source was later improved by Coolidge in the early 20^{th} century [see, for example, William D. Coolidge, U.S. Pat. No. 1,211,092, issued Jan. 2, 1917, U.S. Pat. No. 1,917,099, issued Jul. 4, 1933, and U.S. Pat. No. 1,946,312, issued Feb. 6, 1934], and, later in the 20^{th} century, systems generating very intense beams of x-rays using synchrotrons or free electron lasers (FELs) have been developed. These synchrotron or FEL systems, however, are physically very large systems, requiring large buildings and acres of land for their implementation. For compact, practical lab-based systems and instruments, most x-ray sources today still use the fundamental mechanism of the Coolidge tube.

An example of the simplest x-ray source, a transmission x-ray source 08, is illustrated in FIG. 1. The source comprises a vacuum environment (typically 10⁻⁶ torr or better) commonly provided by a sealed vacuum tube 02 or active pumping, manufactured with sealed electrical leads 21 and 22 that pass from the negative and positive terminals of a high voltage source 10 outside the tube to the various elements inside the vacuum tube 02. The source 08 will typically comprise mounts 03 which secure the vacuum tube 02 in a housing 05, and the housing 05 may additionally comprise shielding material, such as lead, to prevent x-rays from being radiated by the source 08 in unwanted directions.

Inside the vacuum tube 02, an emitter 11 connected through the lead 21 to the high voltage source 10 serves as a cathode and generates a beam of electrons 111, often by running a current through a filament. The target 01 is electrically connected to the opposite high voltage lead 22 to be at low voltage, thus serving as an anode. The emitted electrons 111 accelerate towards the target 01 and collide with it at high energy, with the energy of the electrons determined by the magnitude of the accelerating voltage. The collision of the electrons 111 into the solid target 01 induces several effects, including the emission of x-rays 888, some of which exit the vacuum tube 02 through a window 04 designed to transmit x-rays. In the configuration shown in FIG. 1, the target 01 is deposited or mounted directly on the window 04 and the window 04 forms a portion of the wall of the vacuum chamber. In other prior art embodiments, the target may be formed as an integral part of the window 04 itself.

Another example of a common x-ray source design is the reflection x-ray source 80, is illustrated in FIG. 2. Again, the source comprises a vacuum environment (typically 10⁻⁶ torr or better) commonly maintained by a sealed vacuum tube 20 or active pumping, and manufactured with sealed electrical leads 21 and 22 that pass from the negative and positive terminals of a high voltage source 10 outside the tube to the various elements inside the vacuum tube 20. The source 80 will typically comprise mounts 30 which secure the vacuum tube 20 in a housing 50, and the housing 50 may additionally comprise shielding material, such as lead, to prevent x-rays from being radiated by the source 80 in unwanted directions.

Inside the tube 20, an emitter 11 connected through the lead 21 to the high voltage source 10 serves as a cathode and generates a beam of electrons 111, often by running a current through a filament. A target 100 supported by a target substrate 110 is electrically connected to the opposite high voltage lead 22 and target support 32 to be at low voltage, thus serving as an anode. The electrons 111 accelerate towards the target 100 and collide with it at high energy, with the energy of the electrons determined by the magnitude of the accelerating voltage. The collision of the electrons 111 into the target 100 induces several effects, including the emission of x-rays, some of which exit the vacuum tube 20 and are transmitted through a window 40 that is transparent to x-rays.

In an alternative prior art embodiment for a reflective x-ray source (not shown in FIG. 2), the target 100 and substrate 110 may be integrated or comprise a solid block of the same material, such as copper (Cu). Also not shown in FIGS. 1 and 2, but commonly employed in practice, electron optics (electrostatic or electromagnetic lenses) may be provided to guide and shape the path of the electrons, forming a more concentrated, focused beam at the target. Likewise, electron sources comprising multiple emitters may be provided to provide a larger, distributed source of electrons.

When the electrons collide with a target 100, they can interact in several ways. These are illustrated in FIG. 3. The electrons in the electron beam 111 collide with the target 100 at its surface 102, and the electrons that pass through the surface transfer their energy into the target 100 in an interaction volume 200, generally defined by the incident electron beam footprint (area) times the electron penetration depth. For an incident electron beam of very small size (e.g. a beam diameter <100 nm) the interaction volume 200 is typically “pear” or “teardrop” shaped in three dimensions, and symmetric around the electron propagation direction. For a larger beam, the interaction volume will be represented by the convolution of this “teardrop” shape with the lateral beam intensity profile.

An equation commonly used to estimate the penetration depth for electrons into a material is Pott's Law [P. J. Potts, Electron Probe Microanalysis, Ch. 10 of A Handbook of Silicate Rock Analysis, Springer Netherlands, 1987, p. 336)], which states that the penetration depth x in microns is related to the 10% of the value of the electron energy E₀ in keV raised to the 3/2 power, divided by the density of the material:

$$x ( µm ) = 0.1 \times \frac{{E}_{0}^{1.5}}{ρ} \qquad [ Eqn . 1 ]$$

For less dense material, such as a diamond substrate, the penetration depth is much larger than for a material with greater density, such as most elements used for x-ray generation.

There are several energy transfer mechanisms that can occur. Throughout the interaction volume 200, electron energy may simply be converted into heat. Some absorbed energy may excite the generation of secondary electrons, typically detected from a region 221 located near the surface, while some electrons may also be backscattered, which, due to their higher energy, can be detected from a somewhat larger region 231.

Throughout the interaction volume 200, including in the regions 221 and 231 near the surface and extending approximately 3 times deeper into the target 100, x-rays 888 are generated and radiated outward in all directions. The x-ray emission can have a complex energy spectrum. As the electrons penetrate the material, they decelerate and lose energy, and therefore different parts of the interaction volume 200 produce x-rays with different properties. A typical x-ray radiation spectrum for emission from the collision of 100 keV electrons with a tungsten target is illustrated in FIG. 4.

As shown in FIG. 4, The broad spectrum x-ray emission 388 arises from electrons that were diverted from their initial trajectory, depending on how close they pass to various nuclei and other electrons. The reduction in electron energy and the change momentum associated with the change in direction generate the radiation of x-rays. Because a wide range of deflections and decelerations can occur, due to the proximity statistics of the electron collisions with the atoms of the target material, the change in energy is a continuum, and therefore, the energy of the generated x-rays also is a continuum. Greater emission occurs at the low end of the energy spectrum, with far less occurring at higher energy, and reaching an absolute limit of no x-rays with energy larger than the original electron energy (in this example, 100 keV). Due to their origin in deceleration of electrons, this kind of continuum x-ray emission 388 is commonly called bremsstrahlung, after the German word “bremsen” for “braking”.

These continuum x-rays 388 are generated throughout the interaction volume, shown in FIG. 3 as the largest shaded portion 288 of the interaction volume 200. At lower energy, the bremsstrahlung x-rays 888 are typically emitted isotropically, i.e. with little variation in intensity with emission direction [see, for example, D. Gonzales, B. Cavness, and S. Williams, “Angular distribution of thick-target bremsstrahlung produced by electrons with initial energies ranging from 10 to 20 keV incident on Ag”, Phys. Rev. A, vol. 84, 052726 (2011)], higher energy excitation can have increased emission normal to the electron beam, i.e. at “0 degrees” for an incident beam at 90 degrees with respect to the target surface.

[See, for example, J. G. Chervenak and A. Liuzzi, “Experimental thick-target bremsstrahlung spectra from electrons in the range 10 to 30 kev”, Phys. Rev. A, vol. 12(1), pp. 26-33 (July, 1975).]

As was shown in FIGS. 1 and 2, the x-ray source 08 or 80 will typically have a window 04 or 40. This window 04 or 40 may additionally comprise a filter, such as a sheet or layer of aluminum, that attenuates the low energy x-rays, producing the modified energy spectrum 488 shown in FIG. 4.

When the electron energy is larger than the binding energy of an inner-shell (core-shell) electron of an element within the target, ejection of the electron (ionization) from the shell may occur, creating a vacancy. Electrons from less strongly bound outer shell(s) are then free to transition to the vacant inner shell, filling the vacancy. As the filling electron moves down to the lower energy level, the excess energy is emitted in the form of an x-ray photon. This is known as “characteristic” radiation because the energy of the photon is characteristic of the chemical element that generates the photon.

In the example shown in FIG. 4, an electron of 100 keV may ionize a K-shell electron of a tungsten atom, which has a binding energy of 69.5 keV. If the vacancy is filled by an electron from the L-shell, which has a binding energy of 10.2 keV, the x-ray photon has an energy equal to the energy difference between these two levels, or K_{α1}=59.3 keV. Likewise, a transition from the M-shell to the K-shell is denoted as K_{β1}=67.2 keV. Splittings can occur in the various levels, giving rise to slight variations in energy, e.g. K_{β1}, K_{β2}, K_{β3} etc.

Because these discrete emission lines depend on the atomic structure of the target material, the emission is generally called “characteristic lines”, since they are a characteristic of the particular material. The sharp lines 988 in the example of an x-ray emission spectrum shown in FIG. 4 are “characteristic lines” for tungsten. Individual characteristic lines can be quite bright, and may be monochromatized with an appropriate filter or crystal monochromator where a monochromatic source is desired. The relative x-ray intensity (flux) ratio of the characteristic line(s) to the bremsstrahlung radiation depends on the element and the incident electron energy, and can vary substantially. In general, a maximum ratio for a given target material is obtained when the incident electron energy is 3 to 5 times the ionization energy of the inner shell electrons.

Returning to FIG. 3, these characteristic x-rays 388 are primarily generated in a fraction of the electron penetration depth, shown as the second largest shaded portion 248 of the interaction volume 200. The relative depth is influenced in part by the energy of the electrons 111, which typically falls off with increasing depth. If the electron energy does not exceed the binding energy for electrons within the target, no characteristic x-rays will be emitted at all. The greatest emission of characteristic lines may occur under bombardment with electrons having three to five times the energy of the emitted characteristic x-ray photons. Because these characteristic x-rays result from atomic emission between electron shells, the emission will generally be entirely isotropic. The actual dimensions of this interaction volume 200 may vary, depending on the energy and angle of incidence of the electrons, the surface topography and other properties (including local charge density), and the density and atomic composition of the target material.

For some applications, broad-spectrum x-rays may be appropriate. For other applications, a monochromatic source may be desired or even necessary for the sensitivity or resolution required. In general, the composition of the target material is selected to provide x-ray spectra with ideal characteristics for a specific application, such as strong characteristic lines at particular wavelengths of interest, or bremsstrahlung radiation over a desired bandwidth.

Control of the x-ray emission properties of a source may be governed by the selection of an electron energy (typically changed by varying the accelerating voltage), x-ray target material selection, and by the geometry of x-ray collection from the target.

Although the x-rays may be emitted isotropically, as was illustrated in FIG. 3, only the x-ray emission 888 within a small solid angle in the direction of window 440 in the source, as shown in FIG. 5, will be collected. The x-ray brightness, (also called “brilliance” by some), defined as the number of x-ray photons per second per solid angle in mrad² per area of the x-ray source in mm² (some measures may also include a bandwidth window of 0.1% in the definition), is an important figure of merit for a source, as it relates to obtaining good signal-to-noise ratios for downstream applications.

The brightness can be increased by adjusting the geometric factors to maximize the collected x-rays. As illustrated in FIG. 5, the surface of the target 100 in a reflection x-ray source is generally mounted at an angle θ (as was also shown in FIG. 2) and bombarded by a distributed electron beam 111. Emission through a window 440 is shown for a set of five equally spaced emission spots 408 for three target angles: θ=60° in FIG. 5A, θ=45° in FIG. 5B, and θ=30° in FIG. 5C. For a source at a high angle θ, for a solid angle centered at the window 440, the five spots are more spread out and brightness is reduced, while for low angle θ, the five source spots appear to be closer together, thus emitting more x-rays into the same solid angle and resulting in an increased brightness.

In principle, it may appear that a source mounted at θ=0° would have all sources apparently overlapping, accumulating the emitted x-rays, and therefore would have the largest possible brightness. In practice, emission at 0° occurs parallel to the surface of a solid metal target for conventional sources, and since the x-rays must propagate along a long length of the target material before emission, most of the produced x-rays will be attenuated (reabsorbed) by the target material, reducing brightness. In practice, a source with take-off angle of around 6° to 15° (depending on the source configuration, target material, and electron energy) will often provide the greatest practical brightness, concentrating the apparent size of the source while reducing re-absorption within the target material and is therefore commonly used in commercial x-ray sources.

The effective source area is the projected area viewed along the direction along which x-ray are collected for use, i.e. along the axis of the x-ray beam. Because of the limited electron penetration depth, the effective source area for an incident electron beam with a size comparable or larger than the electron penetration depth is dependent on the angle between the axis of the x-ray beam and the surface of the target, referred to as the “take-off angle”. When the electron beam size is much larger than the electron penetration depth, the effective source area decreases with decreasing take-off angle. This effect has been used to increase x-ray source brightness. However, with an extensive flat target, there is a limit to this benefit, due to the increasing absorption of x-rays from their production points inside the target as they propagate to the surface, which increases with a smaller take-off angle. Typically, a compromise between improved brightness from a lower angle and reduced brightness from reabsorption is reached around a take-off angle of ˜6 degrees.

Another way to increase the brightness of the x-ray source for bremsstrahlung radiation is to use a target material with a higher atomic number Z, as efficiency of x-ray production for bremsstrahlung radiation scales with increasingly higher atomic number materials. Furthermore, the x-ray emitting material should ideally have good thermal properties, such as a high melting point and high thermal conductivity, in order to allow higher electron power loading on the source to increase x-ray production. For these reasons, targets are often fabricated using tungsten, with an atomic number Z=74. Table I lists several materials that are commonly used for x-ray targets, several additional potential target materials (notably useful for specific characteristic lines of interest), and some materials that may be used as substrates for target materials. Melting points, and thermal and electrical conductivities are presented for values near 300° K (27° C.). Most values are cited from the CRC Handbook of Chemistry and Physics, 90^{th} ed. [CRC Press, Boca Raton, Fla., 2009]. Other values are cited from various sources found on the Internet. Note that, for some materials, such as sapphire for example, thermal conductivities an order of magnitude larger may be possible when cooled to temperatures below that of liquid nitrogen (77° K) [see, for example, Section 2.1.5, Thermal Properties, of E. R. Dobrovinskaya et al., Sapphire: Material, Manufacturing, Applications, Springer Science+Business Media, LLC (2009)]

Other ways to increase the brightness of the x-ray source are: increasing the electron current density, either by increasing the overall current or by focusing the electron beam to a smaller spot using, for example, electron optics; or by increasing the electron energy by increasing the accelerating voltage (which increases x-ray production per unit electron energy deposited in the target, and may excite more emission in the characteristic lines as well).

However, these improvements have a limit, in that all can increase the amount of heat generated in the interaction volume. The problem is exacerbated by having the target in a vacuum, so no air cooling from the surface by convection may occur. If too much heat is generated within the target, the target material may undergo phase changes, even as far as melting or evaporating. Because the vast majority of the energy deposited into

TABLE 1
Various Target and Substrate Materials and Selected Properties.

| | | | | |
|---|---|---|---|---|
| Material | Atomic | Melting | Thermal | Electrical |
| (Elemental | Number | Point ° C. | Conductivity | Conductivity |
| Symbol) | Z | (1 atm) | (W/(m ° C.)) | (MS/m) |

Common Target Materials:

| | | | | |
|---|---|---|---|---|
| Chromium (Cr) | 24 | 1907 | 93.7 | 7.9 |
| Iron (Fe) | 26 | 1538 | 80.2 | 10.0 |
| Cobalt (Co) | 27 | 1495 | 100 | 17.9 |
| Copper (Cu) | 29 | 1085 | 401 | 58.0 |
| Molybdenum (Mo) | 42 | 2623 | 138 | 18.1 |
| Silver (Ag) | 47 | 962 | 429 | 61.4 |
| Tungsten (W) | 74 | 3422 | 174 | 18.4 |

Other Possible Target Materials:

| | | | | |
|---|---|---|---|---|
| Titanium (Ti) | 22 | 1668 | 21.9 | 2.6 |
| Gallium (Ga) | 35 | 30 | 40.6 | 7.4 |
| Rhodium (Rh) | 45 | 1964 | 150 | 23.3 |
| Indium (In) | 49 | 157 | 81.6 | 12.5 |
| Cesium (Cs) | 55 | 28 | 35.9 | 4.8 |
| Rhenium (Re) | 75 | 3185 | 47.9 | 5.8 |
| Gold (Au) | 79 | 1064 | 317 | 44.0 |
| Lead (Pb) | 82 | 327 | 35.3 | 4.7 |

Other Potential Substrate Materials with low atomic number:

| | | | | |
|---|---|---|---|---|
| Beryllium (Be) | 4 | 1287 | 200 | 26.6 |
| Carbon (C): | 6 | * | 2300 | 10⁻¹⁹ |
| Diamond | | | | |
| Carbon (C): | 6 | * | 1950 | 0.25 |
| Graphite ∥ | | | | |
| Carbon (C): | 6 | * | 3180 | 100.0 |
| Nanotube (SWNT) | | | | |
| Carbon (C): | 6 | * | 200 | |
| Nanotube (bulk) | | | | |
| Boron Nitride (BN) | B = 5 | ** | 20 | 10⁻¹⁷ |
| | N = 7 | | | |
| Silicon (Si) | 14 | 1414 | 124 | 1.56 × 10⁻⁹ |
| Silicon Carbide | Si = 14 | 2798 | 0.49 | 10⁻⁹ |
| (β-SiC) | C = 6 | | | |
| Sapphire | Al = 13 | 2053 | 32.5 | 10⁻²⁰ |
| (Al₂O₃) ∥ C | O = 8 | | | |

* Carbon does not melt at 1 atm; it sublimes at ~3600° C.
** BN does not melt at 1 atm; it sublimes at ~2973° C.

the target by an electron beam becomes heat, thermal management techniques are an important tool for building better x-ray sources.

One prior art technology that has been developed to address this problem is the rotating anode system, illustrated in FIG. 6. In FIG. 6A, a cross-section is shown for a rotating anode x-ray source 580 comprising a target anode 500 that typically rotates between 3,300 and 10,000 rpm. The target anode 500 is connected by a shaft 530 to a rotor 520 supported by conducting bearings 524 that connect, through its mount 522, to the lead 22 and the positive terminal of the high voltage supply 10. The rotation of the rotor 520, shaft 530 and anode 500, all within the vacuum chamber 20, is typically driven inductively by stator windings 525 mounted outside the vacuum.

The surface of the target anode 500 is shown in more detail in FIG. 6B. The edge 510 of the rotating target anode 500 is sometimes beveled at an angle, and the source of the electron beam 511 is in a position to direct the electron beam onto the beveled edge 510 of the target anode 500, generating x-rays 888 from a target spot 501. As the target spot 501 generates x-rays, it heats up, but as the target anode 500 rotates, the heated spot moves away from the target spot 501, and the electron beam 511 now irradiates a cooler portion of the target anode 500. The hot spot has the time of one rotation to cool before becoming heated again when it passes through the hot spot 501. By continuously rotating the target anode 500, x-rays are generated from a fixed single spot, while the total area of the target illuminated by the electron beam is substantially larger than the electron beam spot, effectively spreading the electron energy deposition over a larger area (and volume).

Another approach to mitigating heat is to use a target with a thin layer of target x-ray material deposited onto a substrate with high heat conduction. Because the interaction volume is thin, for electrons with energies up to 100 keV the target material itself need not be thicker than a few microns, and can be deposited onto a substrate, such as diamond, sapphire or graphite that conducts the heat away quickly. However, as noted in Table I, diamond is a very poor electrical conductor, so the design of any anode fabricated on a diamond substrate must still provide an electrical connection between the target material of the anode and the positive terminal of the high voltage. [Diamond mounted anodes for x-ray sources have been described by, for example, K. Upadhya et al. U.S. Pat. No. 4,972,449; B. Spitsyn et. al. U.S. Pat. No. 5,148,462; and M. Fryda et al., U.S. Pat. No. 6,850,598].

The substrate may also comprise channels for a coolant, for example liquids such as water or ethylene glycol, or a gas such as hydrogen or helium, that remove heat from the substrate [see, for example, Paul E. Larson, U.S. Pat. No. 5,602,899] Water-cooled anodes are used for a variety of x-ray sources, including rotating anode x-ray sources.

The substrate may in turn be mounted to a heat sink comprising copper or some other material chosen for its thermally conducting properties. The heat sink may also comprise channels for a coolant, to transport the heat away [See, for example, Edward J. Morton, U.S. Pat. No. 8,094,784]. In some cases, thermoelectric coolers or cryogenic systems have been used to provide further cooling to an x-ray target mounted onto a heat sink, again, all with the goal of achieving higher x-ray brightness without melting or damaging the target material through excessive heating.

Another approach to mitigating heat for microfocus sources is to use a target created by a jet of liquid metal. Electrons bombard a conducting jet of liquid gallium (Z=31), and because the heated gallium flows away from the electron irradiation volume with the jet, higher current densities are possible. [See, for example, M. Otendal, et al., “A 9 keV electron-impact liquid-gallium-jet x-ray source”, Rev. Sci. Instrum., vol. 79, 016102, (2008)].

Although effective in certain circumstances, there is still room for improvement in these sources. Jets of liquid metal require an elaborate plumbing system and consumables, are limited in the materials (and thus values of Z and their associated spectra) that may be used, and are difficult to scale to larger output powers. In the case of thin film targets of uniform solid material coated onto diamond substrates, there is still a limitation in the amount of heat that can be tolerated before damage to the film may occur, even if used in a rotating anode configuration. Conduction of heat only occurs through the bottom of the film. In a lateral dimension, the same conduction problem exists as exists in the bulk material.

There is therefore a need for a practical method for fabricating a target for use in an x-ray source that may be used to achieve higher x-ray brightness through the use of a higher electron current density. Once fabricated, such a target can be used as a component of brighter x-ray source, enabling x-ray based tools that offer better signal to noise ratios in imaging and other applications.

### BRIEF SUMMARY

This disclosure presents configurations for x-ray targets for use in generating x-rays from electron beam bombardment. The x-ray target configurations comprise a number of microstructures of a selected x-ray generating material fabricated in close thermal contact with (such as embedded in) a substrate with high thermal conductivity, such that the heat is more efficiently drawn out of the x-ray generating material. This in turn allows irradiation of the x-ray generating material with higher electron density or higher energy electrons, which leads to greater x-ray brightness.

The microstructures may comprise any number of conventional x-ray target materials (such as copper (Cu), and molybdenum (Mo) and tungsten (W)) that are patterned as features of micron scale dimensions on (or embedded in) a thermally conducting substrate, such as diamond or sapphire. In some embodiments, the microstructures may alternatively comprise unconventional x-ray target materials, such as tin (Sn), sulfur (S), titanium (Ti), antimony (Sb), etc. that have thus far been limited in their use due to poor thermal properties. The microstructures may take any number of geometric shapes, such as cubes, rectangular blocks, regular prisms, right rectangular prisms, trapezoidal prisms, spheres, ovoids, barrel shaped objects, cylinders, triangular prisms, pyramids, tetrahedra, or other particularly designed shapes, including those with surface textures or structures that enhance surface area, to best generate x-rays of high brightness and that also efficiently disperse heat.

In some embodiments, the target may additionally comprise an electrically conducting overcoat or internal layer to give the electrons a path to complete an electrical circuit, for example, serving as an anode relative to a high voltage source of electrons.

In some embodiments, the target comprising microstructures may be incorporated into a rotating anode geometry, to enhance x-ray generation in such systems.

In some embodiments, the target comprising microstructures may be structured such that, with certain incident electron beam orientations, increased x-ray transmission at near-zero take-off angles will be observed.

In some embodiments, the target comprising microstructures may be designed to improve thermal dissipation.

### BRIEF DESCRIPTION OF THE DRAWINGS

FIG. 1 illustrates a cross-section diagram of a standard prior art transmission x-ray source.

FIG. 2 illustrates a cross-section diagram of a standard prior art reflection x-ray source.

FIG. 3 illustrates a cross-section diagram the interaction of electrons with a surface of a material in a prior art x-ray source.

FIG. 4 illustrates the typical emission spectrum for a tungsten target.

FIG. 5A illustrates emission from a prior art target for a target at a tilt angle of 60 degrees.

FIG. 5B illustrates emission from a prior art target for a target at a tilt angle of 45 degrees.

FIG. 5C illustrates emission from a prior art target for a target at a tilt angle of 30 degrees.

FIG. 6A illustrates a cross-section view of a prior art rotating anode x-ray source.

FIG. 6B illustrates a top view of the anode for the rotating anode system of FIG. 6A.

FIG. 7 illustrates a perspective view of a target according to the invention comprising a grid of embedded rectangular target microstructures on a larger substrate.

FIG. 8 illustrates a perspective view of a variation of a target according to the invention comprising a grid of embedded rectangular target microstructures on a larger substrate for use with focused electron beam.

FIG. 9 illustrates a perspective view of a variation of a target according to the invention comprising a grid of embedded rectangular target microstructures on a truncated substrate.

FIG. 10 illustrates a perspective view of a variation of a target according to the invention comprising a grid of embedded rectangular target microstructures on a substrate with a recessed shelf.

FIG. 11 illustrates a cross-section view of electrons entering a target according to the invention comprising target microstructures on a larger substrate.

FIG. 12 illustrates a cross-section view of some of the x-rays emitted by the target of FIG. 11.

FIG. 13A illustrates a perspective view of a target according to the invention comprising a grid of embedded rectangular target microstructures.

FIG. 13B illustrates a top view of the target of FIG. 13A.

FIG. 13C illustrates a side/cross-section view of the target of FIGS. 13A and 13B.

FIG. 14A illustrates a cross-section view of the target of FIG. 13, showing thermal transfer to a thermally conducting substrate under electron beam exposure.

FIG. 14B illustrates a cross-section view of a variation of the target of FIG. 13 and FIG. 14A comprising a substrate with a thermal cooling channel.

FIG. 15 illustrates a cross-section view of another variation of the target of FIG. 13 comprising an adhesion layer according to the invention.

FIG. 16 illustrates a cross-section view of another variation of the target of FIG. 13 comprising an electrically conducting overcoat according to the invention.

FIG. 17 illustrates a cross-section view of another variation of the target of FIG. 13 comprising buried x-ray material according to the invention.

FIG. 18 illustrates a cross-section view of another variation of the target of FIG. 13 in which the target microstructure comprises several material layers according to the invention.

FIG. 19 illustrates a cross-section view of another variation of the target of FIG. 13 comprising buried x-ray material and a thick thermally and electrically conducting overcoat according to the invention.

FIG. 20A illustrates a perspective view of a target according to the invention comprising two grids of embedded target microstructures at different depths.

FIG. 20B illustrates a top view of the target of FIG. 20A.

FIG. 20C illustrates a side/cross-section view of the target of FIGS. 20A and 20B.

FIG. 21A illustrates a cross-section view of the target of FIG. 20 according to the invention, showing thermal transfer under electron beam exposure when the buried structures are in electrical contact with the embedded structures.

FIG. 21B illustrates a cross-section view of the target of FIG. 20 according to the invention, showing thermal transfer under electron beam exposure when the buried structures have an additional electrically conducting layer.

FIG. 22A illustrates a perspective view of a target according to the invention comprising an array of microstructures comprising embedded trapezoidal prisms.

FIG. 22B illustrates a top view of the target of FIG. 22A.

FIG. 22C illustrates a side/cross-section depth view of the target of FIGS. 22A and 22B.

FIG. 23A illustrates a perspective view of a target according to the invention comprising a checkerboard configuration of embedded target microstructures.

FIG. 23B illustrates a top view of the target of FIG. 23A.

FIG. 23C illustrates a side/cross-section view of the target of FIGS. 23A and 23B.

FIG. 24A illustrates a perspective view of a target according to the invention comprising a regular grid of embedded cylindrical target microstructures.

FIG. 24B illustrates a top view of the target of FIG. 24A.

FIG. 24C illustrates a side/cross-section view of the target of FIGS. 24A and 24B.

FIG. 25A illustrates a perspective view of a target according to the invention comprising a regular closely packed grid of embedded cylindrical target microstructures.

FIG. 25B illustrates a top view of the target of FIG. 25A.

FIG. 25C illustrates a side/cross-section view of the target of FIGS. 25A and 25B.

FIG. 26A illustrates a perspective view of a target according to the invention comprising a regular closely packed grid of embedded triangular target microstructures.

FIG. 26B illustrates a top view of the target of FIG. 26A.

FIG. 26C illustrates a side/cross-section view of the target of FIGS. 26A and 26B.

FIG. 27A illustrates a perspective view of a target according to the invention comprising a regular closely packed grid of embedded tetrahedral target microstructures.

FIG. 27B illustrates a top view of the target of FIG. 27A.

FIG. 27C illustrates a side/cross-section view of the target of FIGS. 27A and 27B.

FIG. 28A illustrates a perspective view of a target according to the invention comprising a two-level checkerboard layout of target microstructures.

FIG. 28B illustrates a top view of the target of FIG. 28A.

FIG. 28C illustrates a side/cross-section view of the target of FIGS. 28A and 28B.

FIG. 29A illustrates a perspective view of a target according to the invention comprising a two-level layout of target microstructures arranged in an “alternating woodpile array” configuration.

FIG. 29B illustrates a top view of the target of FIG. 29A.

FIG. 29C illustrates a side/cross-section view of the target of FIGS. 29A and 29B.

FIG. 30A illustrates a perspective view of a target according to the invention comprising a regular closely packed grid of embedded spherical target microstructures.

FIG. 30B illustrates a top view of the target of FIG. 30A.

FIG. 30C illustrates a side/cross-section view of the target of FIGS. 30A and 30B.

FIG. 31 illustrates a top view of a target according to the invention comprising a variety of spherical target microstructures fabricated from a single target material.

FIG. 32 illustrates a top view of a target according to the invention comprising a variety of spherical target microstructures fabricated from two target materials.

FIG. 33 illustrates a perspective view of a target according to the invention comprising a single rectangular microstructure arranged on a substrate with a recessed region.

FIG. 34 illustrates a perspective view of a target according to the invention comprising a multiple rectangular microstructure arranged in a line on a substrate with a recessed region.

FIG. 35A illustrates a perspective view of a target according to the invention comprising a grid of embedded rectangular target microstructures arranged on a tiered substrate.

FIG. 35B illustrates a top view of the target of FIG. 35A.

FIG. 35C illustrates a side/cross-section view of the target of FIGS. 35A and 35B.

FIG. 36 illustrates a cross-section view of the target of FIG. 35 radiating x-rays under electron bombardment.

FIG. 37 illustrates a top down view of a rotating anode x-ray source according to the invention comprising a variety of target microstructures fabricated in an annular configuration.

FIG. 38 illustrates a flow diagram for a set of steps for making an x-ray target according to one embodiment of the invention.

FIG. 39A illustrates the structures created during an initial sequence of manufacturing steps while making an x-ray target according to one embodiment of the invention.

FIG. 39B illustrates the structures created during a second sequence of manufacturing steps while making an x-ray target according to one embodiment of the invention.

FIG. 40 illustrates the structures created during a sequence of manufacturing steps incorporating an adhesion layer while making an x-ray target according to one embodiment of the invention.

### DETAILED DESCRIPTIONS

### 1. Introduction

In this writing, embodiments for targets for generating x-rays using electron beams are disclosed, along with their method of manufacture. A target according to the invention comprises a number of regions fabricated from an x-ray generating material arranged in close thermal contact with a substrate such that heat is more efficiently drawn out of the x-ray generating substance. This in turn allows irradiation of the x-ray generating substance with higher electron density or higher energy electrons, which leads to greater x-ray brightness. To achieve this increased heat transfer, the target comprises a plurality of regions of x-ray generating material in close thermal contact with a substrate made from a material selected for its high thermal conductivity. The x-ray generating material may be any material known to generate x-rays, including conventional materials such as copper (Cu), molybdenum (Mo) or tungsten (W). The substrate may be any material that has high thermal conductivity, and may also be chosen to be a low Z material, so that the electron energy deposition rate in the substrate is less than in the x-ray generating material, and the substrate is less likely to heat up with exposure to the incident electrons.

### 2. Embodiments of the Invention

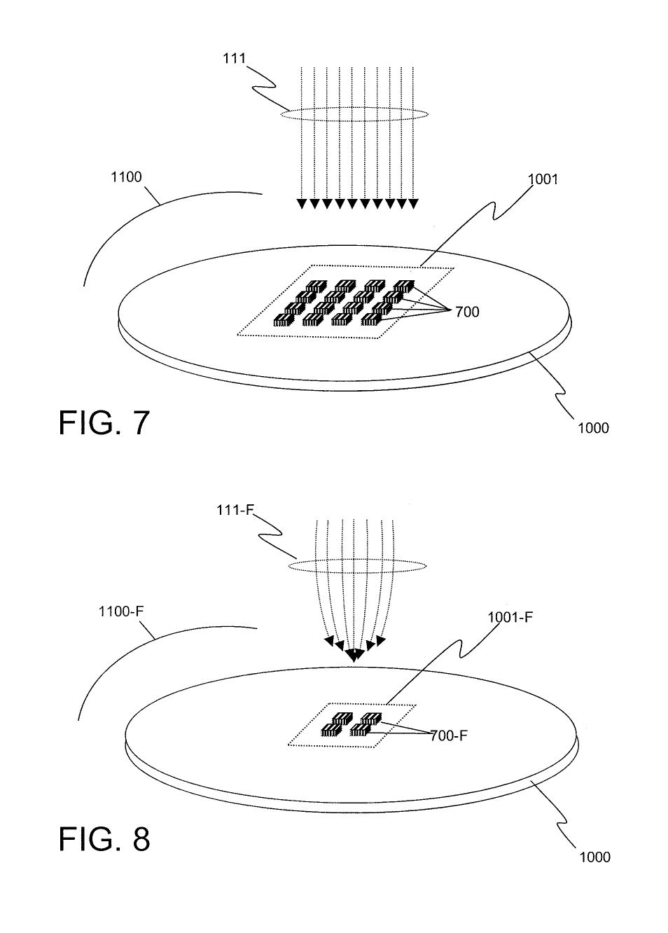

FIG. 7 illustrates an embodiment of a target according to the invention. In this figure, a substrate 1000 has a region 1001 that comprises an array of microstructures 700 comprising x-ray generating material (typically a metallic material) that are arranged in a regular array of right rectangular prisms. In a vacuum, electrons 111 bombard the target from above, and generate heat and x-rays in the microstructures 700. The material in the substrate 1000 is selected such that it has relatively low energy deposition rate for electrons in comparison to the x-ray generating microstructure material (typically by selecting a low Z material for the substrate), and therefore will not generate a significant amounts of heat and x-rays. The substrate 1000 material may also be chosen to have a high thermal conductivity, typically larger than 100 W/(m ° C.), and the microstructures are typically embedded within the substrate, i.e. if the microstructures are shaped as rectangular prisms, it is preferred that at least five of the six sides are in close thermal contact with the substrate 1000, so that heat generated in the microstructures 700 is effectively conducted away into the substrate 1000. However, other embodiments may have fewer direct contact surfaces. In general, when the term “embedded” is used in this disclosure, at least half of the surface area of the microstructure will be in close thermal contact with the substrate.

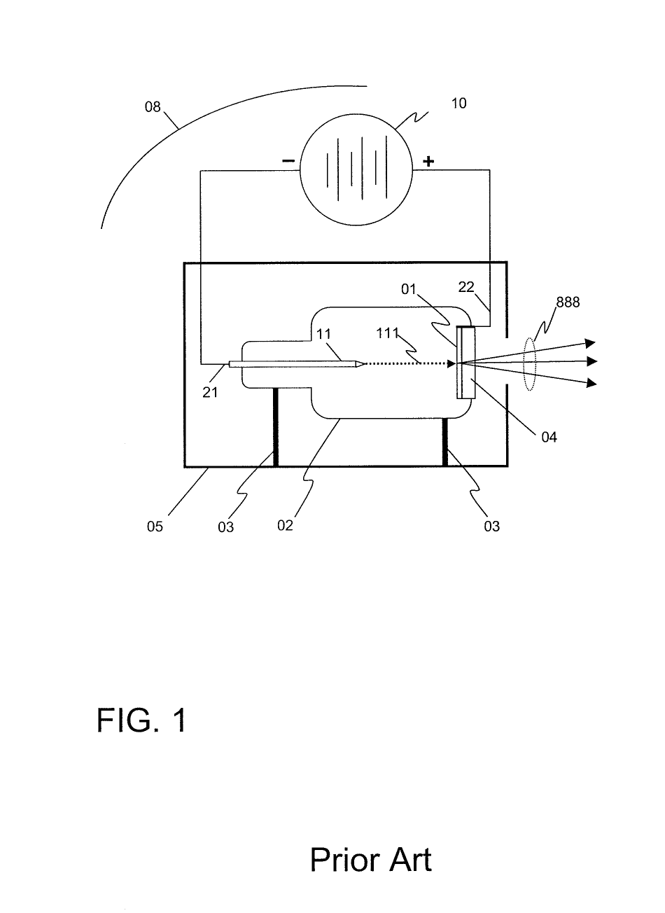

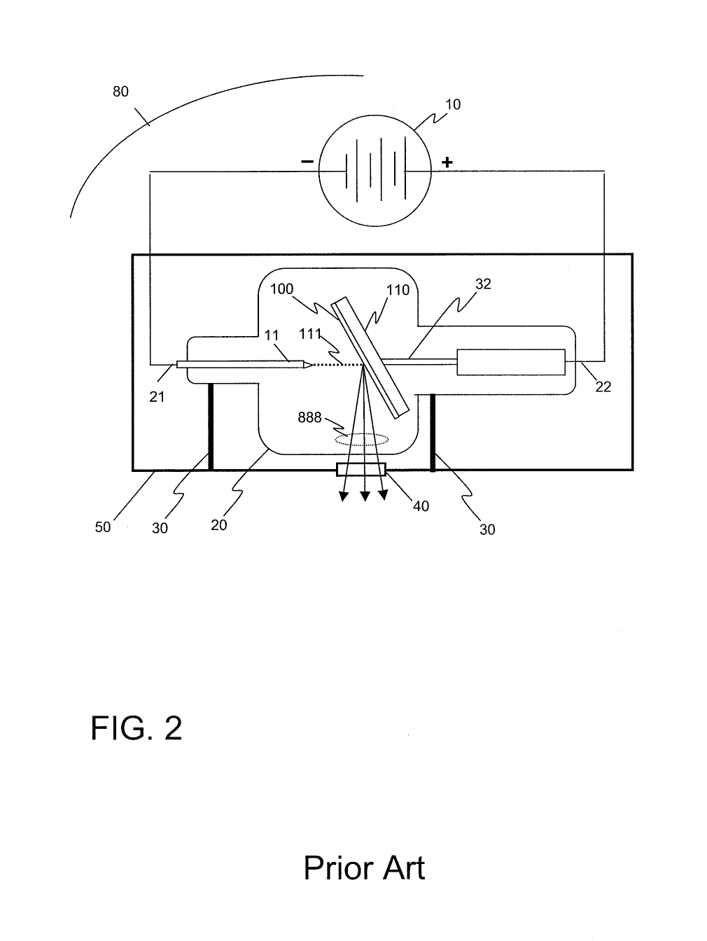

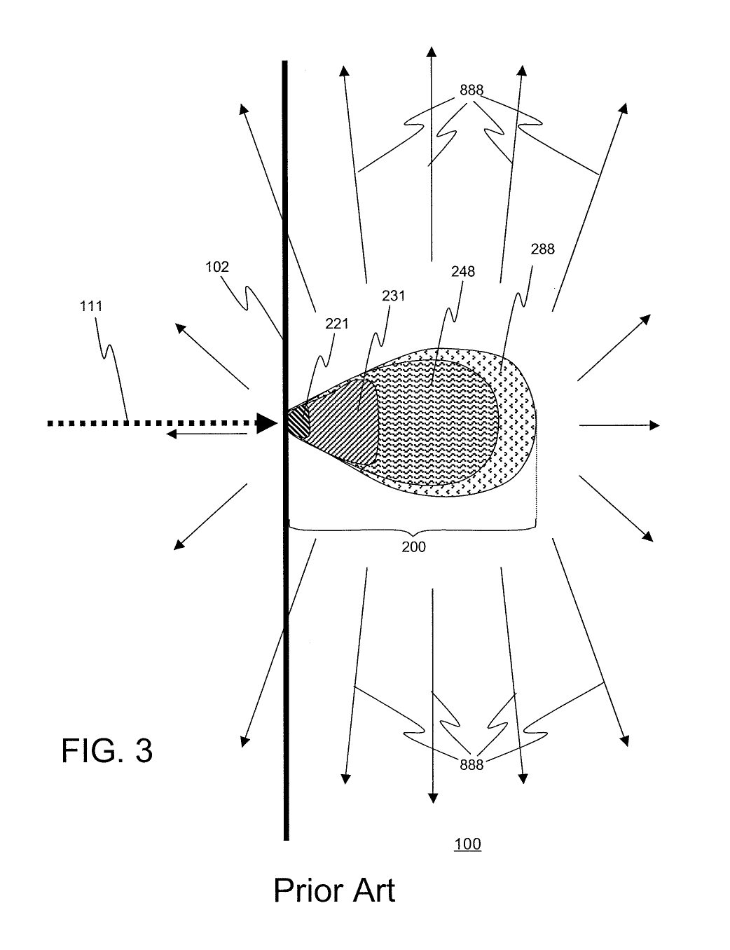

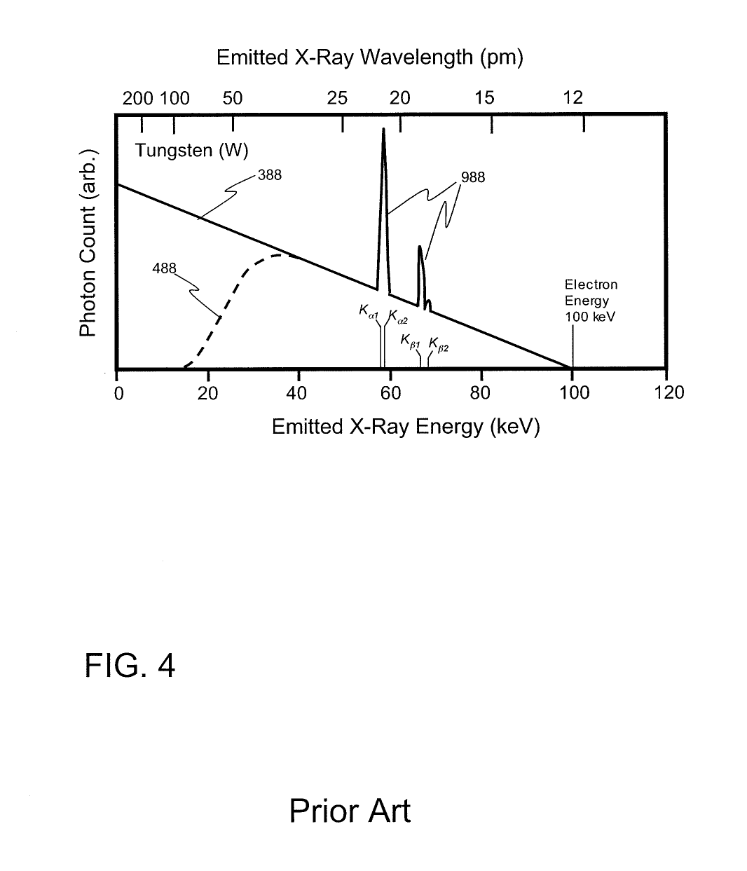

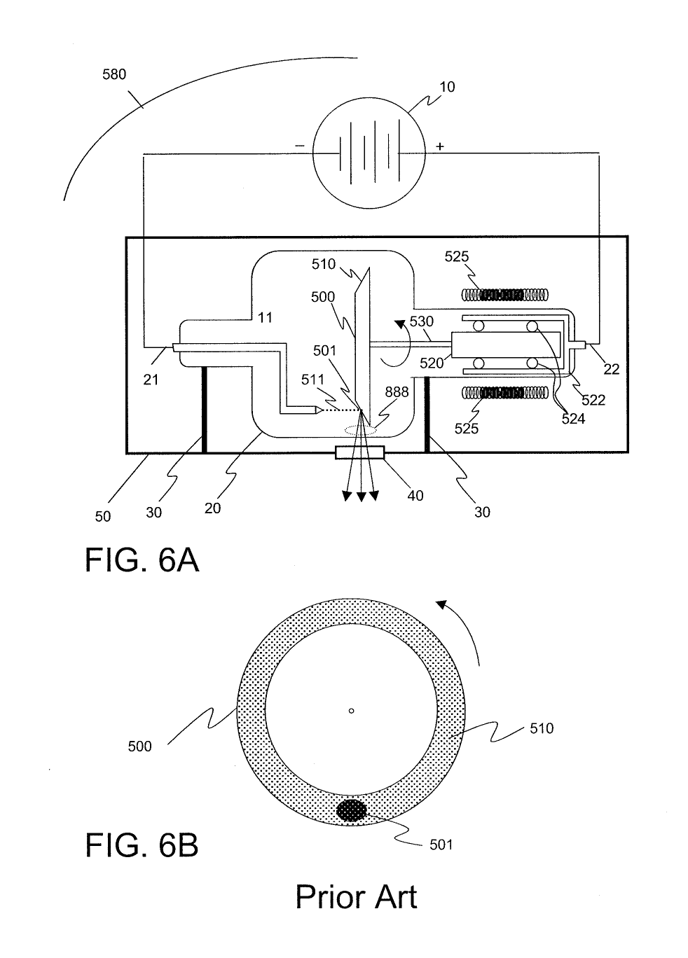

A target 1100 according to the invention may be inserted as a replacement for the target 01 for the transmission x-ray source 08 illustrated in FIG. 1, or for the target 100 illustrated in the reflecting x-ray source 80 of FIG. 2, or adapted for use as the target 500 used in the rotating anode x-ray source 580 of FIG. 6.

It should be noted here that, when the word “microstructure” is used herein, it is specifically referring to microstructures comprising x-ray generating material. Other structures, such as the cavities used to form the x-ray microstructures, have dimensions of the same order of magnitude, and might also be considered “microstructures”. As used herein, however, other words, such as “structures”, “cavities”, “holes”, “apertures”, etc. may be used for these structures when they are formed in materials, such as the substrate, that are not selected for their x-ray generating properties. The word “microstructure” will be reserved for structures comprising materials selected for their x-ray generating properties.

Likewise, it should be noted that, although the word “microstructure” is used, x-ray generating structures with dimensions smaller than 1 micron, or even as small as nano-scale dimensions (i.e. greater than 10 nm) may also be described by the word “microstructures” as used herein.

FIG. 8 illustrates another embodiment of the invention, to be used in a source in which the electron beam 111-F is directed by electrostatic lenses to form a more concentrated, focused spot. For this situation, the target 1100-F will still comprise a region 1001-F comprising an array of microstructures 700-F comprising x-ray material, but the size and dimensions of this region 1001-F can be matched to regions where electron exposure will occur. In these embodiments, the “tuning” of the source geometry and the x-ray generating material can be controlled such that the designs mostly limit the amount of heat generated to the microstructured region 1001-F, while also reducing the design and manufacturing complexity. This may be especially useful when used with electron beams focused to form a micro-spot, or by more intricate systems that form a more complex electron exposure pattern.

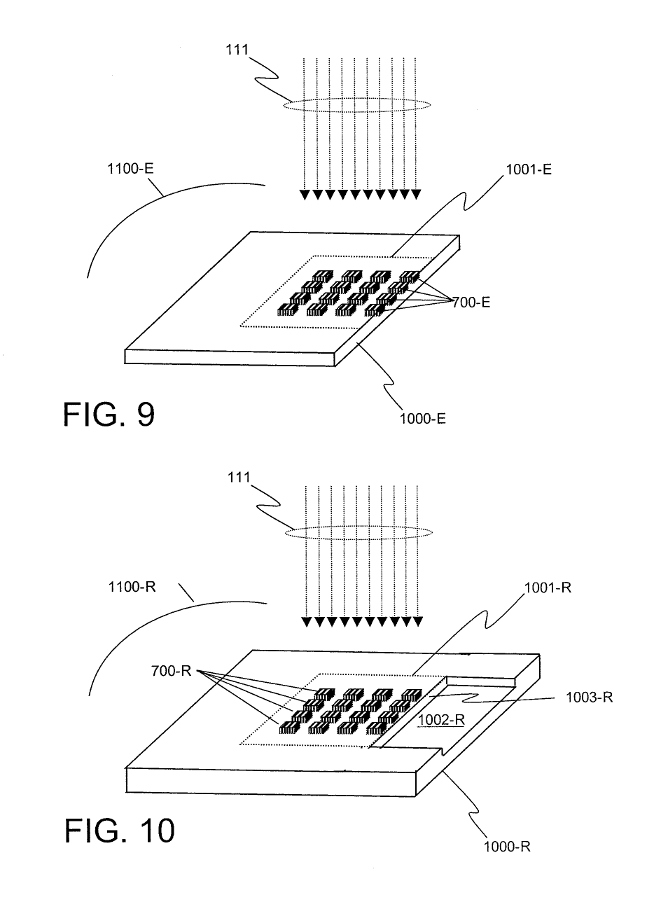

FIG. 9 illustrates another embodiment of the invention, in which the target 1100-E still has a region 1001-E with an array of microstructures 700-E comprising x-ray material that emit x-rays when exposed to electrons 111, but the region 1001-E is positioned flush with or near the edge of the substrate 1000-E. This configuration may be useful in targets where the substrate comprises a material that absorbs x-rays, and so emission at near-zero angles would be significantly attenuated in a configuration, as was shown in FIG. 7.

A disadvantage of the embodiment of FIG. 9, however, as compared to FIG. 7 is that a significant portion of the substrate on one side of the microstructures 700-E is gone. Heat therefore is not carried away from the microstructures symmetrically, and the local heating may increase, impairing heat flow.

To address this, some embodiments of the invention may use a configuration like that shown in FIG. 10. Here, the target 1100-R comprises a substrate 1000-R with a recessed shelf 1002-R. This allows the region 1001-R comprising an array of microstructures 700-R to be positioned flush with, or close to, a recessed edge 1003-R of the substrate, and emit x-rays at or near zero angle without being reabsorbed by the substrate 1000-R, yet provides a more symmetric heat sink for the heat generated when exposed to electrons 111.

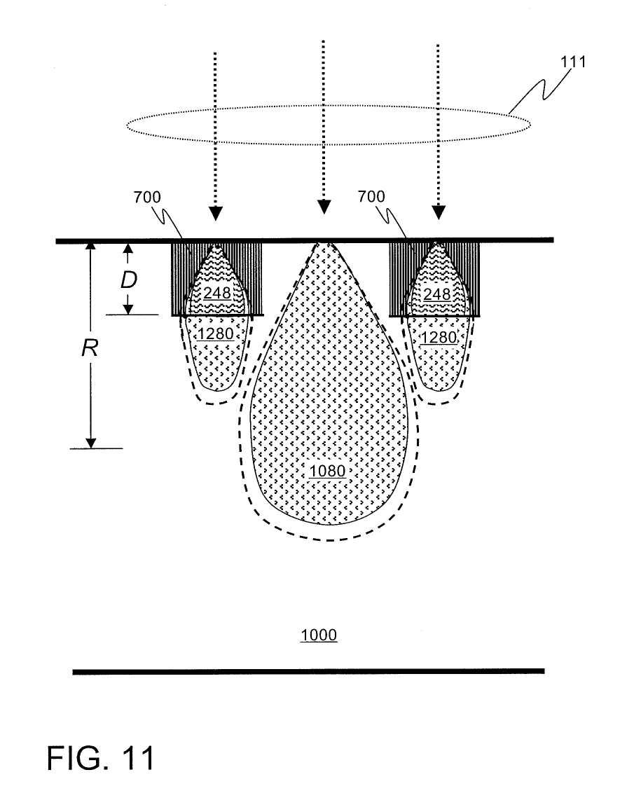

FIG. 11 illustrates the relative interaction between a beam of electrons 111 and a target comprising a substrate 1000 and microstructures 700 of x-ray material. As illustrated, only three electron paths are shown, with two representative of electrons bombarding the two shown microstructures 700, and one interacting with the substrate.

As discussed in Eqn. 1 above, the depth of penetration can be estimated by Pott's Law. Using this formula, Table II illustrates some of the estimated penetration depths for some common x-ray target materials.

TABLE II
Estimates of penetration depth for 60
keV electrons into some materials.

| | | Density | Penetration Depth |
|---|---|---|---|
| Material | Z | (g/cm³) | (μm) |
| Diamond | 6 | 3.5 | 13.28 |
| Copper | 29 | 8.96 | 5.19 |
| Molybdenum | 42 | 10.28 | 4.52 |
| Tungsten | 74 | 19.25 | 2.41 |

For the illustration in FIG. 11, if 60 keV electrons are used, and diamond (Z=6) is selected as the material for the substrate 1000 and copper (Z=29) is selected as the x-ray generating material for the microstructures 700, the dimension marked as R to the left side of FIG. 11 corresponds to a reference dimension of 10 microns, and the depth D in the x-ray generating material, which, when set to be ⅔ (66%) of the electron penetration depth for copper, becomes D≈3.5 μm.

The majority of characteristic Cu K x-rays are generated within depth D. The electron interactions below that depth typically generate few characteristic K-line x-rays but will contribute to the heat generation, thus resulting in a low thermal gradient along the depth direction. It is therefore preferable in some embodiments to set a maximum thickness for the microstructures in order to limit electron interaction in the material and optimize local thermal gradients. One embodiment of the invention limits the depth of the microstructured x-ray generating material to between one third and two thirds of the electron penetration depth at the incident electron energy. In this case, the lower mass density of the substrate leads to a lower energy deposition rate in the substrate material immediately below the x-ray generating material, which in turn leads to a lower temperature in the substrate material below. This results in a higher thermal gradient between the x-ray generating material and the substrate, enhancing heat transfer. The thermal gradient is further enhanced by the high thermal conductivity of the substrate material.

For similar reasons, selecting the depth D to be less than the electron penetration depth is also generally preferred for efficient generation of bremsstrahlung radiation, because the electrons below that depth have lower energy and thus lower x-ray production efficiency.

Note: Other choices for the dimensions of the x-ray generating material may also be used. In some embodiments, the depth of the x-ray material may be selected to be 50% of the electron penetration depth. In other embodiments, the depth of the x-ray material may be selected to be 33% of the electron penetration depth. Other depths may be specified depending on the x-ray spectrum desired and the properties of the selected x-ray material.

Note: In other embodiments, a particular ratio between the depth and the lateral dimensions (such as width W and length L) of the x-ray generating material may also be specified. For example, if the depth is selected to be a particular dimension D, then the lateral dimensions W and/or L may be selected to be no more than 5×D, giving a maximum ratio of 5. In other embodiments, the lateral dimensions W and/or L may be selected to be no more than 2×D. It should also be noted that the depth D and lateral dimensions W and L (for width and length of the x-ray generating microstructure) may be defined relative to the axis of electron propagation, or defined with respect to the orientation of the surface of the x-ray generating material. For normal incidence electrons, these will be the same dimensions. For electrons incident at an angle, care must be taken to make sure the appropriate projections are used.

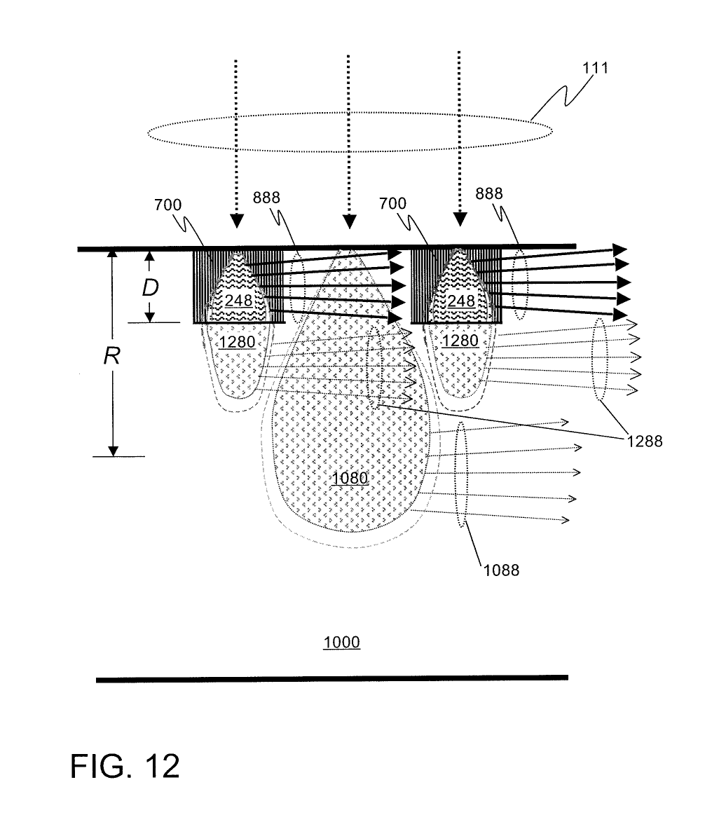

FIG. 12 illustrates the relative x-ray generation from the various regions shown in FIG. 11. X-rays 888 comprise characteristic x-rays emitted from the region 248 where they are generated in the x-ray generating material, while the regions 1280 and 1080 where the electrons interact with the substrate generate characteristic x-rays of the substrate element(s), (but not characteristic x-rays of the element(s) of the x-ray generating material in the x-ray generating region 248). Additionally, bremsstrahlung radiation x-rays emitted from the region 248 of the x-ray generating material are typically much stronger than in the regions 1280 and 1080 where electrons encounter only the low Z substrate, which emit weak continuum x-rays 1088 and 1228.

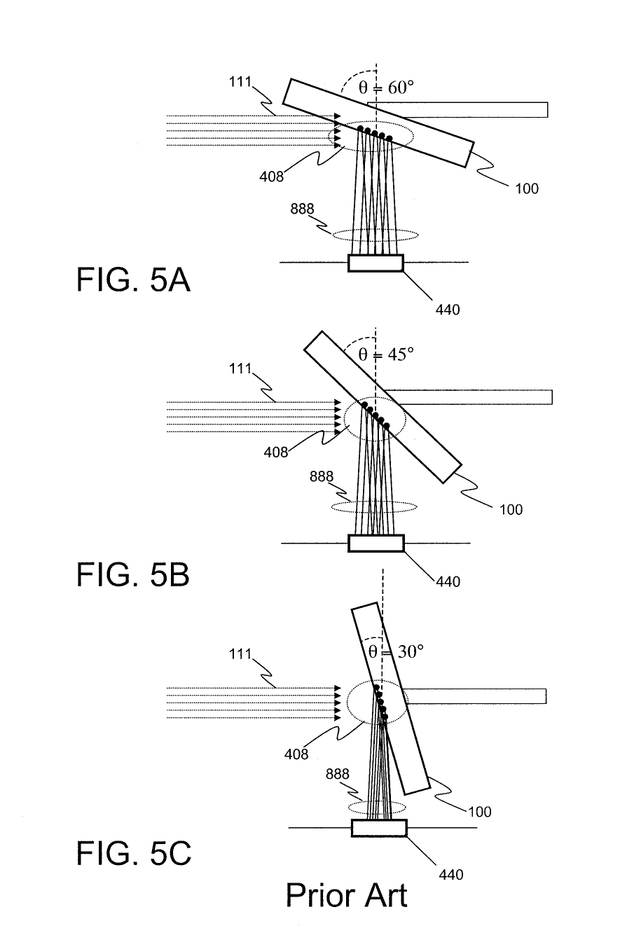

It should be noted that, although the illustration of FIG. 12 shows x-rays emitted only to the right, this is in anticipation of a window or collector being placed to the right, when this target is used in the low-angle high-brightness configuration discussed in FIG. 5. X-rays are in fact typically emitted in all directions from these regions.

It should also be noted that materials are relatively transparent to their own characteristic x-rays, so that FIG. 12 illustrates an arrangement that allows the linear accumulation of characteristic x-rays along the microstructures and therefore can produce a relatively strong characteristic x-ray signal. However, many lower energy x-rays will be attenuated by the target materials, which will effectively act as an x-ray filter. Other selections of materials and geometric parameters may be chosen (e.g. a non-linear scheme) if non-characteristic, continuum x-rays are desired, such as applications in which a bandpass of low energy x-rays are desired (e.g. for imaging or fluorescence analysis of low Z materials).

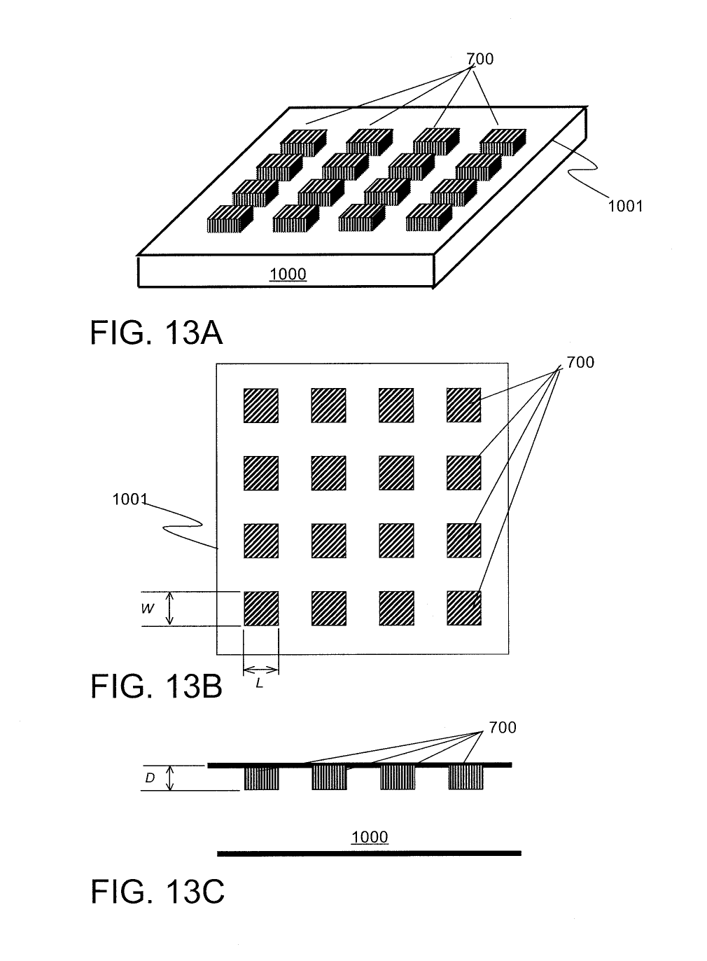

FIG. 13 illustrates a region 1001 of a target according to an embodiment of the invention that comprises an array of microstructures 700 in the form of right rectangular prisms comprising x-ray generating material arranged in a regular array. FIG. 13A presents a perspective view of the sixteen microstructures 700 in this embodiment, while FIG. 13B illustrates a top down view of the same region, and FIG. 13C presents a side/cross-section view of the same region. (For the term “side/cross-section view” in this disclosure, the view meant is one as if a cross-section of the object had been made, and then viewed from the side towards the cross-sectioned surface. This shows both detail at the point of the cross-section as well as material deeper inside that might be seen from the side, assuming the substrate itself were transparent [which, in the case of diamond, is generally true for visible light].)

In this embodiment, the microstructures have been fabricated such that they are in close thermal contact on five of six sides with the substrate. As illustrated, the top of the microstructures 700 are flush with the surface of the substrate, but other embodiments in which the microstructure is recessed may be fabricated, and still other embodiments in which the microstructures present a topographical “bump” relative to the surface of the substrate may also be fabricated.

An alternative embodiment may have several microstructures of right rectangular prisms simply deposited upon the surface of the substrate. In this case, only the bottom base of the prism would be in thermal contact with the substrate. For a structure comprising the microstructures embedded in the substrate with a side/cross-section view as shown in FIG. 13C with depth D and lateral dimensions in the plane of the substrate of W and L, the ratio of the total surface area in contact with the substrate for the embedded microstructures vs. deposited microstructures is

$$\frac{{A}_{Embedded}}{{A}_{Deposited}} = 1 + 2 D \frac{( W + L )}{( W \times L )} \qquad [ Eqn . 2 ]$$

With a small value for D relative to W and L, the ratio is essentially 1. For larger thicknesses, the ratio becomes larger, and for a cube (D=W=L) in which 5 equal sides are in thermal contact, the ratio is 5. If a cap layer of a material with similar properties as the substrate in terms of mass density and thermal conductivity is used, the ratio may be increased to 6.

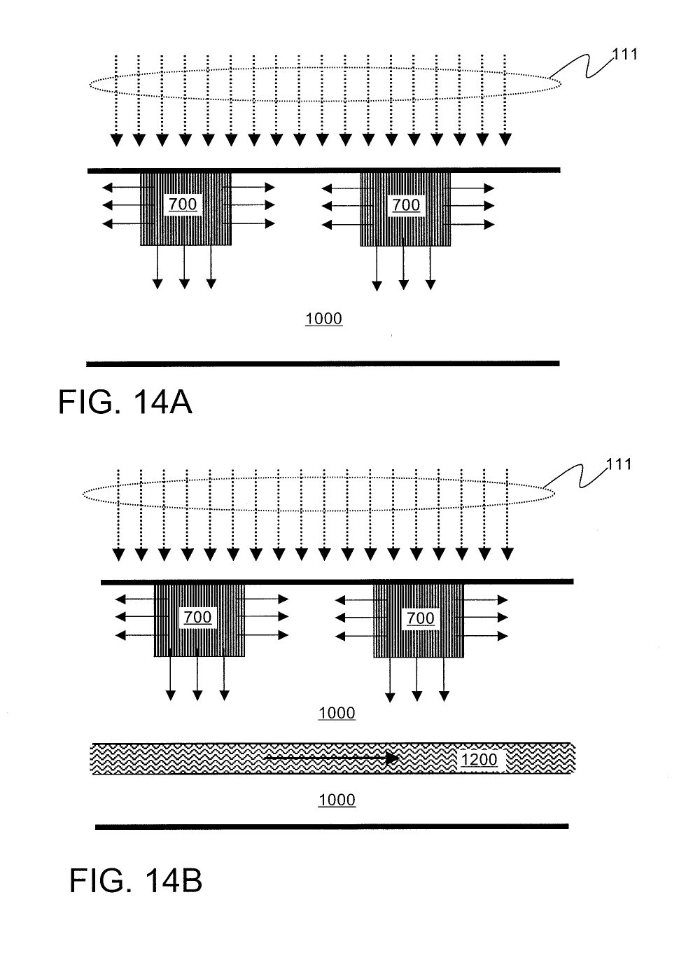

The heat transfer is illustrated with representative arrows in FIG. 14A, in which the heat generated in microstructures 700 embedded in a substrate 1000 is conducted out of the microstructures 700 through the bottom and sides (arrows for transfer through the sides out of the plane of the drawing are not shown). The amount of heat transferred per unit time (ΔQ) conducted through a material of area A and thickness d given by:

$$Δ Q = \frac{κ \cdot A \cdot Δ T}{d} \qquad [ Eqn . 3 ]$$

where κ is the thermal conductivity in W/(m ° C.) and ΔT is the temperature difference across thickness d in ° C. Therefore, an increase in surface area A, a decrease in thickness d and an increase in ΔT all lead to a proportional increase in heat transfer.

An alternative embodiment is illustrated in FIG. 14B, in which the substrate additionally comprises a cooling channel 1200. Such cooling channels may be a prior art cooling channel, as discussed above, using water or some other cooling fluid to conduct heat away from the substrate, or may be fabricated according to a design adapted to best remove heat from the regions near the embedded microstructures 700.

Other embodiments may be understood or devised by those skilled in the art, in which the substrate may, for example, be bonded to a heat sink, such as a copper block, for improved thermal transfer. The copper block may in turn have cooling channels within it to assist in carrying heat away from the block. Alternatively, the substrate may be attached to a thermoelectric cooler, in which a voltage is applied to a specially constructed semiconductor device. In these devices, the flow of current causes one side to cool while the other heats up. Commercially available devices, such as Peltier coolers, can produce a temperature difference of up to 70° C. across the device, but may be limited in their overall capacity to remove large amounts of heat from a heat source.

Alternatively, the substrate can be attached to a cryogenic cooler, such as a block containing channels for the flow of liquid nitrogen, or be in thermal contact with a reservoir of liquid nitrogen or some other cryogenic substance, to provide more extreme cooling. When the substrate comprises a material such as diamond, sapphire, silicon, or silicon carbide, thermal conductivity generally increases with decreasing temperature from room temperature. In such a case, designing the target so that it can withstand cooling to these lower temperatures may be preferred.

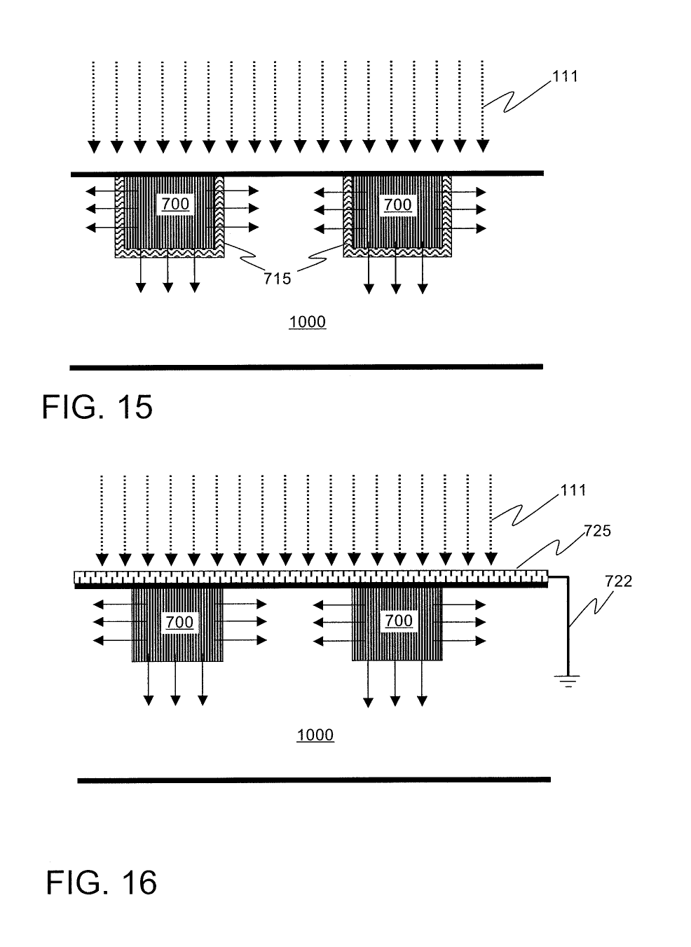

FIG. 15 illustrates an alternative embodiment in which the cavities formed in the substrate 1000 are first coated with an adhesion layer 715 (preferably of minimal thickness) before embedding the x-ray generating material that forms the microstructures 700. Such an adhesion layer may be appropriate in cases where the bond between the x-ray material and the substrate material is weak. The adhesion layer may also act as a buffer layer when the difference between thermal expansion coefficients for the two materials is large. For some choices of materials, the adhesion layer may be replaced or extended (by adding another layer) with a diffusion barrier layer to prevent the diffusion of material from the microstructures into the substrate material (or vice versa). For embodiments in which an adhesion and/or diffusion barrier layer is used, the selection of materials and thicknesses should consider the thermal properties of the layer as well, such that heat flow from the microstructures 700 to the substrate 1000 is not significantly impeded or insulated by the presence of the adhesion layer 715.

FIG. 16 illustrates an alternative embodiment in which an electrically conducting layer 725 has been added to the surface of the target. When bombarded by electrons, the excess charge needs a path to return to ground for the target to function effectively as an anode. If the target as illustrated in FIG. 13 were to comprise only discrete, unconnected microstructures 700 within an electrically insulating substrate material (such as undoped diamond), under continued electron bombardment, significant charge would build up on the surface. The electrons from the cathode would then not collide with the target with the same energy, or might even be repelled, diminishing the generation of x-rays.

This can be addressed by the deposition of a thin layer of conducting material that is preferably of relatively low atomic number, such as aluminum (Al), beryllium (Be), carbon (C), chromium (Cr) or titanium (Ti), that allows electrical conduction from the discrete microstructures 700 to an electrical path 722 that connects to a positive terminal relative to the high voltage supply. This terminal as a practical matter is typically the electrical ground of the system, while the cathode electron source is supplied with a negative high voltage.

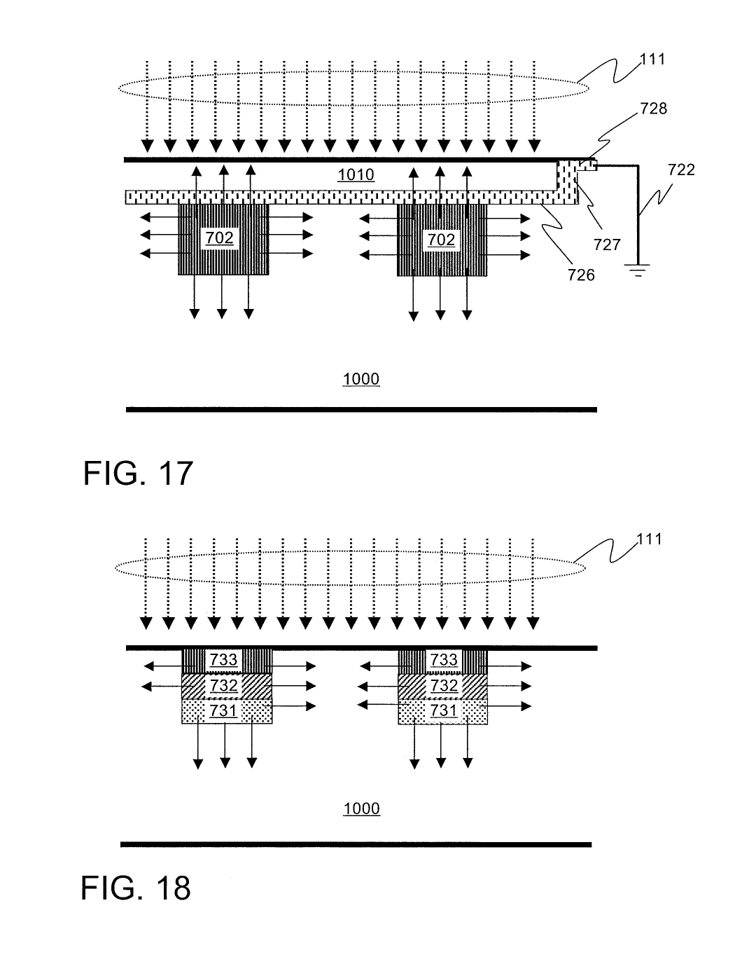

FIG. 17 illustrates another embodiment of the invention, in which the microstructures 702 are embedded deeper, or buried, into the substrate 1000. Such an embedded microstructure may be further covered by the deposition of an additional layer 1010, which may be, for example, diamond, providing the same heat transfer properties as the substrate. This allows heat to be conducted away from all sides of the buried microstructure 702. For such a situation, however, it is advisable to provide a path 722 to ground for the electrons incident on the structure, which may be in the form of a embedded conducting layer 726 laid down before the deposition of the additional layer 1010. In some embodiments, this conducting layer 726 will have a “via” 727, or a vertical connection, often in the form of a pillar or cylinder, that provides an electrically conducting structure to link the embedded conducting layer 726 to an additional conducting layer 728 on the surface of the target, which in turn is connected to the path 722 to ground.

FIG. 18 illustrates another embodiment of the invention, in which the microstructures in turn comprise additional structures within them. Instead of a uniform microstructure, the microstructure is shown having a bottom layer 731, a middle layer 732, and a top layer 733. These layers may be selected to comprise different x-ray generating materials, such that the volume emits multiple characteristic lines. Alternatively, instead of having distinct layers, a microstructure comprising a number of materials arranged side-by-side may be used to achieve a desired x-ray emission spectrum. Alternatively, instead of having distinct layers, a microstructure comprising a uniform or non-uniform mixture or alloy of two or more materials may be used to achieve a desired x-ray emission spectrum. Another embodiment comprises having the middle layer 732 comprise the same material as that of the substrate, to provide high thermal dissipation for the top layer 733 and the bottom layer. Additionally, a conductive layer along the side wall (not shown) may be added to provide an electrical path to a conductive path, as was shown in FIGS. 16 and 17.

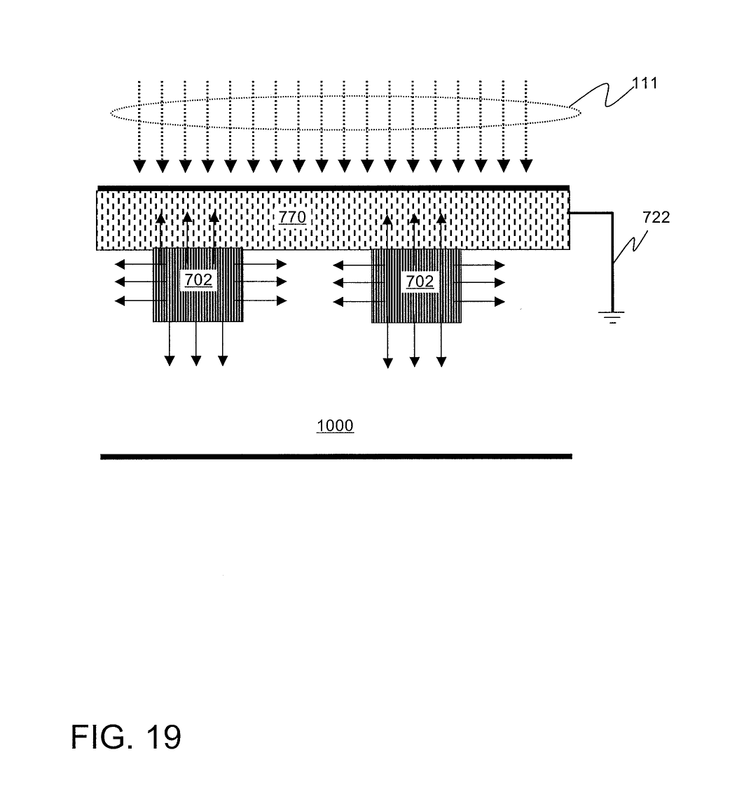

FIG. 19 illustrates another embodiment of the invention, in which the microstructures 702 are again buried within the substrate. However, in this embodiment, instead of first providing an electrically conducting layer followed by the deposition of an additional cap layer, in this embodiment only a single layer 770 is deposited, selected for a combination of electrical properties and thermally conducting properties. This may be, for example, a deposition of carbon nanotubes (Z=6) oriented vertically relative to the surface, such that they conduct both heat and electrons away from the buried microstructures 702. This single layer 770 may in turn be connected to a path 722 to ground to allow the target to serve as an anode in the x-ray generation system. Alternatively, the material of the layer 770 may be selected to comprise aluminum (Al), beryllium (Be), chromium (Cr), or copper (Cu).

It should be clear to those skilled in the art that although several embodiments have been presented separately in FIGS. 13-19, and various processes for their manufacture will be presented later, the elements of these embodiments may be combined with each other, or combined with other commonly known target fabrication methods known in the art. For example, the buried microstructures 702 of FIG. 19 may also comprise multiple materials, as was illustrated in FIG. 18. Likewise, the adhesion layer 715 as illustrated in FIG. 15 may also be applied to fabrication of embedded microstructures 700 as shown in FIG. 16. The separation of these alternatives is for illustration only, and is not meant to be limiting for any particular process.

Although the microstructures illustrated in FIGS. 13-19 have been shown as regularly spaced patterns with uniform size and shape, an irregular or random pattern of uniform microstructures, or a regular pattern of microstructures having non-uniform size and shape, or an irregular pattern of microstructures having non-uniform size and shape can also be used in embodiments of the invention.

Likewise, although some embodiments have been described with microstructures in, for example, the shape of right rectangular prisms, fabrication processes may create structures that have walls at angles other than 90°, or do not have corners that are exactly right angles, but may be rounded or beveled or undercut, depending on the artifacts of the specific process used. Embodiments in which the microstructures are essentially similar with the shapes described herein will be understood by those skilled in the art to be disclosed, even if process artifacts lead to some deviation from the shapes as illustrated or described.

Likewise, although the various examples disclosed herein may be illustrated with ordered periodic arrays of microstructures, the relative position, size and shape of the discrete microstructures need not be regular, periodic, or uniform. Arrangements of microstructures that have a distribution of sizes, with spacing between microstructures that can have a range of distances, may also be functional.

### 3. Various Microstructure Geometries

Certain embodiments of the invention have been described in the previous section. However, aside from variations in layers and structures, various embodiments will comprise microstructures of various sizes and shapes as well.

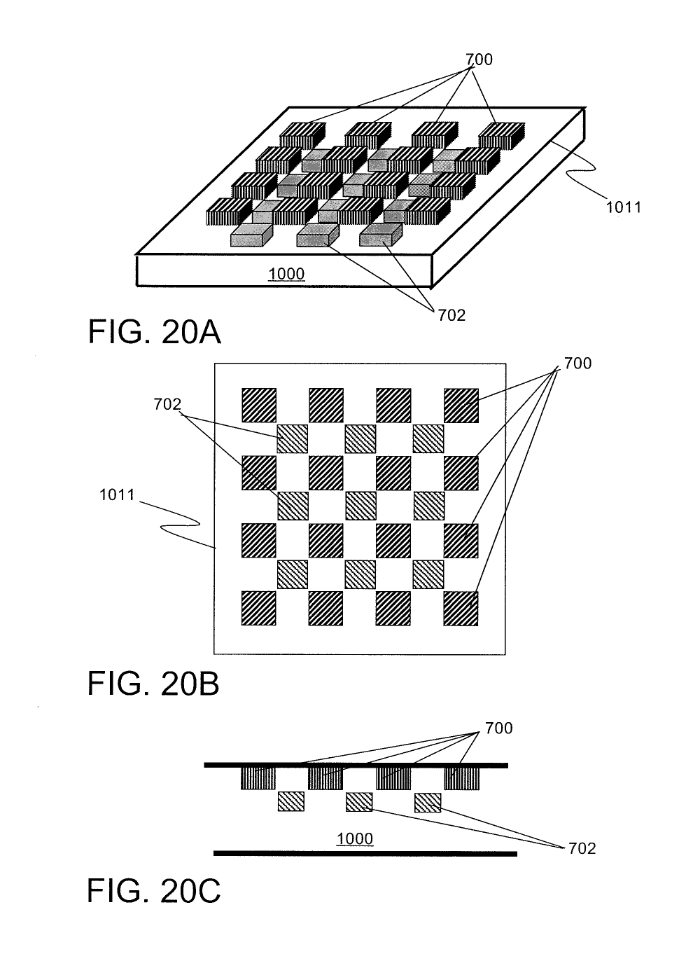

FIG. 20 illustrates a region 1011 of a target according to an embodiment of invention that comprises two regular arrays of microstructures 700 and 702 in the form of right rectangular prisms comprising x-ray generating material, typically a metal. The arrays are staggered laterally and at different depths such that, when under electron irradiation, each of the microstructure is surrounded by the “cooler” substrate material. The physical separation of the microstructures provides small hot spots in a sea of cooler material, thus generating many local thermal gradients that rapidly dissipate heat from the microstructures. FIG. 20A presents a perspective view of the sixteen embedded microstructures 700 and the nine buried microstructures 702 in this embodiment, while FIG. 20B illustrates a top down view of the same region, and FIG. 20C presents a side/cross-section view of the same region.

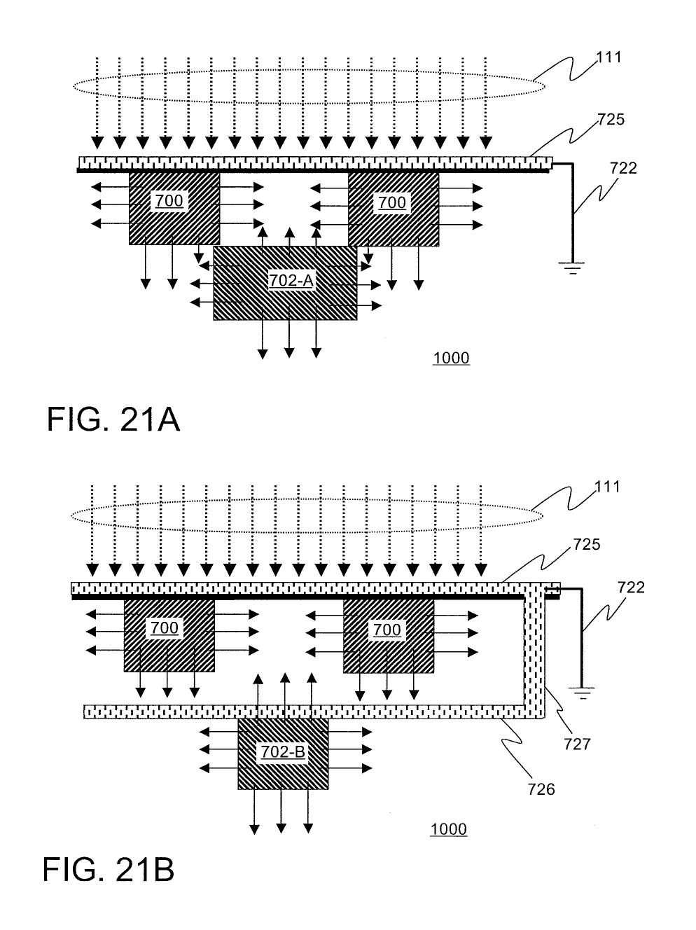

As illustrated in FIG. 21A, the buried microstructures 702-A may be fabricated to be slightly larger than the embedded microstructures 700, such that electrical contact is established between the structures on different layers. If the buried microstructures 702-A have sufficient electrical conductivity, a single electrically conducting layer 725 providing a path 725 to ground may therefore be sufficient to prevent charging of both layers.

On the other hand, the configuration illustrated in FIG. 21A may, for some settings of electron energy and material composition, provide too small an area to provide effective heat transfer and electrical conduction.

To address this, as illustrated in FIG. 21B, the buried microstructures 702-B may be fabricated to be buried deeper into the substrate 1000, and have their own conducting layer 726 connected by a via 727 to provide an additional electrical connection to the path 722 to ground for the buried microscructures 702-B. This configuration provides more distance between the sources of heat and x-rays, and for some applications may be preferred.

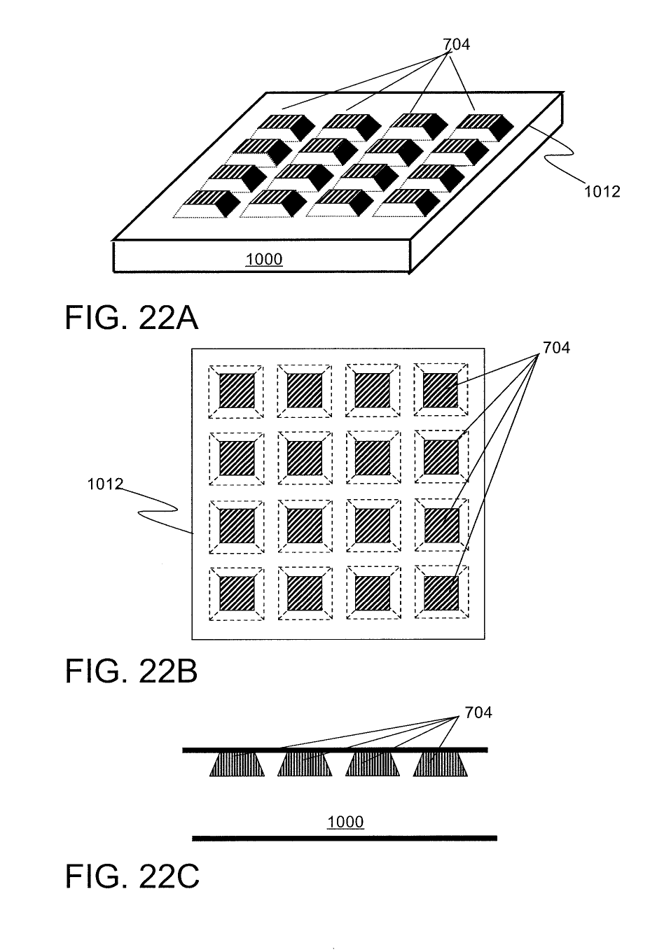

For some fabrication processes, the etching process can be tuned to provide an undercut. [See, for example, D. S. Hwang, T. Saito and N. Fujimori, “New etching process for device fabrication using diamond”, Diamond & Related Materials vol. 13, pp. 2207-2210 (2004) for examples of both isotropic and anisotropic etching of diamond.] If a process with an undercut is selected to etch the cavities in the substrate that are used to form the microstructures, and the microstructures are formed using an isotropic process such as electroplating, which can fill all portions of the cavity, microstructures that are “secured” in place may be formed, as is illustrated in FIG. 22.

FIG. 22 illustrates a region 1012 of a target according to an embodiment of invention that comprises an array of microstructures 704 that have been formed by filling cavities having an undercut in the substrate 1000. The microstructures 704 so formed are in the form of trapezoidal prisms comprising x-ray generating material. The array as shown is arranged as an embedded array in the surface of the substrate, and the “lip” or remaining substrate material around the top serves to better hold the microstructures 704 in place, preventing its detachment under stress or thermal overload. FIG. 22A presents a perspective view of the sixteen embedded trapezoidal microstructures 704 in this embodiment, while FIG. 22B illustrates a top down view of the same region, and FIG. 22C presents a side/cross-section view of the same region.

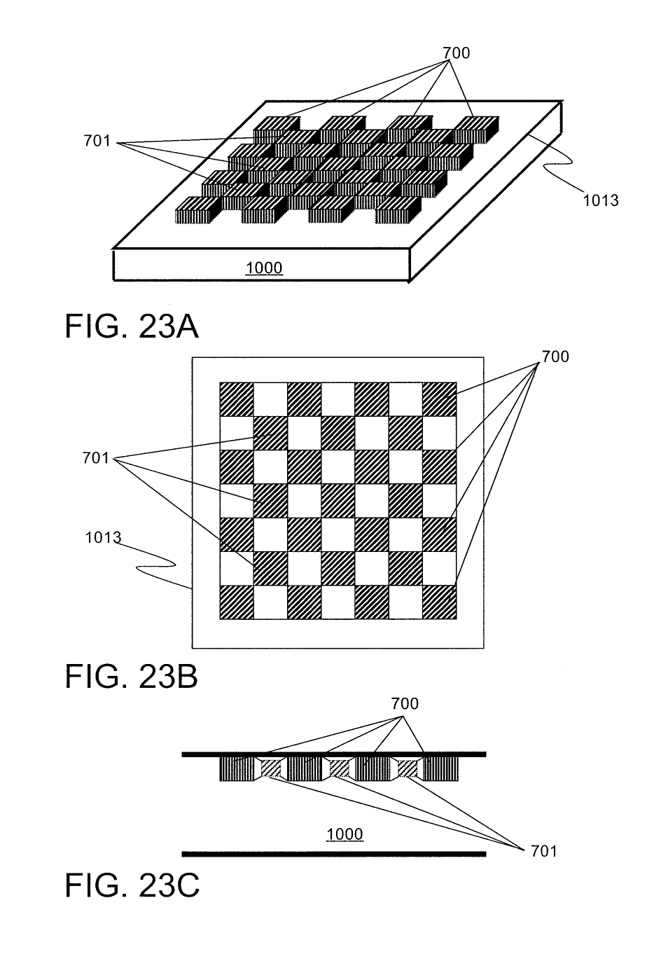

FIG. 23 illustrates a region 1013 of a target according to an embodiment of invention that comprises a checkerboard array of microstructures 700 and 701 in the form of right rectangular prisms comprising x-ray generating material. The array as shown is arranged as an embedded array in the surface of the substrate. FIG. 23A presents a perspective view of the twenty-five embedded microstructures 700 and 701 in this embodiment, while FIG. 23B illustrates a top down view of the same region, and FIG. 23C presents a side/cross-section view of the same region with recessed regions shown with dotted lines.

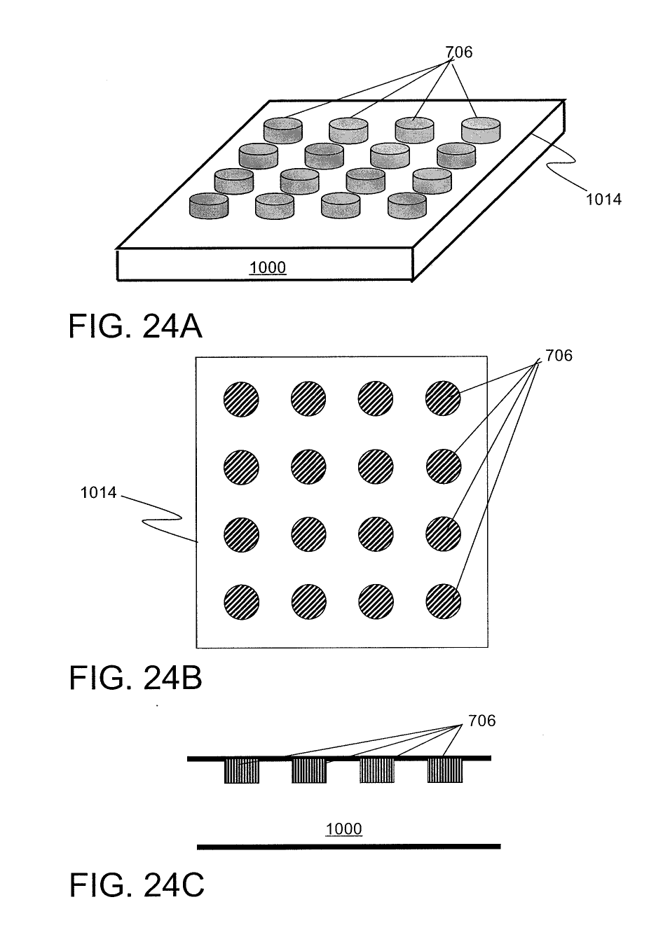

FIG. 24 illustrates a region 1014 of a target according to an embodiment of invention that comprises an array of microstructures 706 in the form of right regular cylinders comprising x-ray generating material. The array as shown is arranged as an array embedded in the substrate. FIG. 24A presents a perspective view of the sixteen embedded microstructures 706 in this embodiment, while FIG. 24B illustrates a top down view of the same region, and FIG. 24C presents a side/cross-section view of the same region across the center of a row of the microstructure 706.

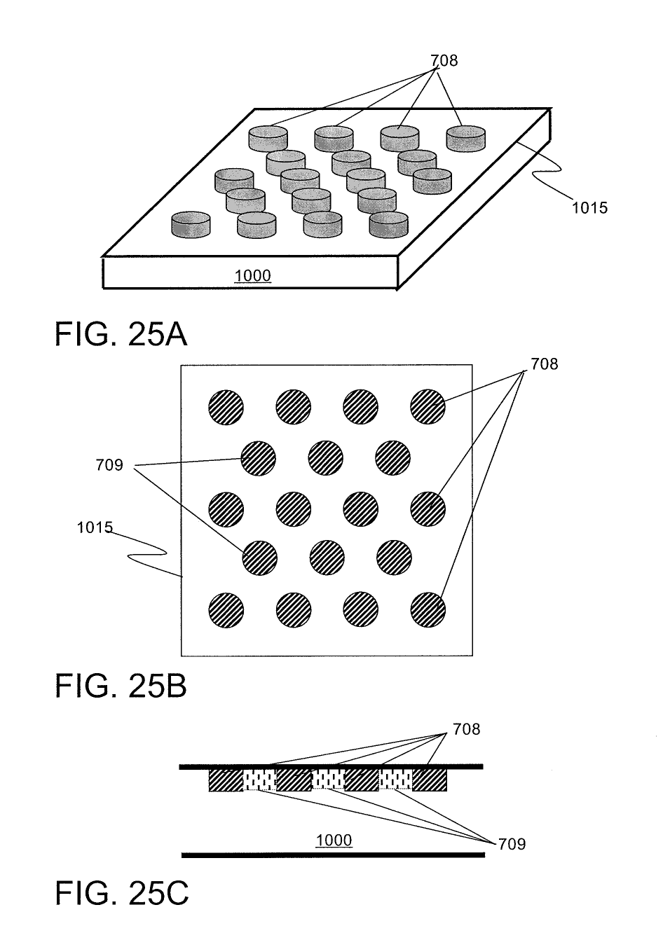

FIG. 25 also illustrates a region 1015 of a target according to an embodiment of invention that comprises a closely packed array of microstructures 708 and 709 in the form of right regular cylinders comprising x-ray generating material. The closely packed array as shown is also arranged as an embedded array in the surface of the substrate. In this embodiment, however, the arrangement is such that, when viewed from the side or end, there appear to be are no “gaps” in the source of the x-rays, as there would be for the arrangement of FIG. 24. FIG. 25A presents a perspective view of the eighteen embedded microstructures 708 and 709 in this embodiment, while FIG. 25B illustrates a top down view of the same region, and FIG. 25C presents a side/cross-section view of the same region with depth perception.

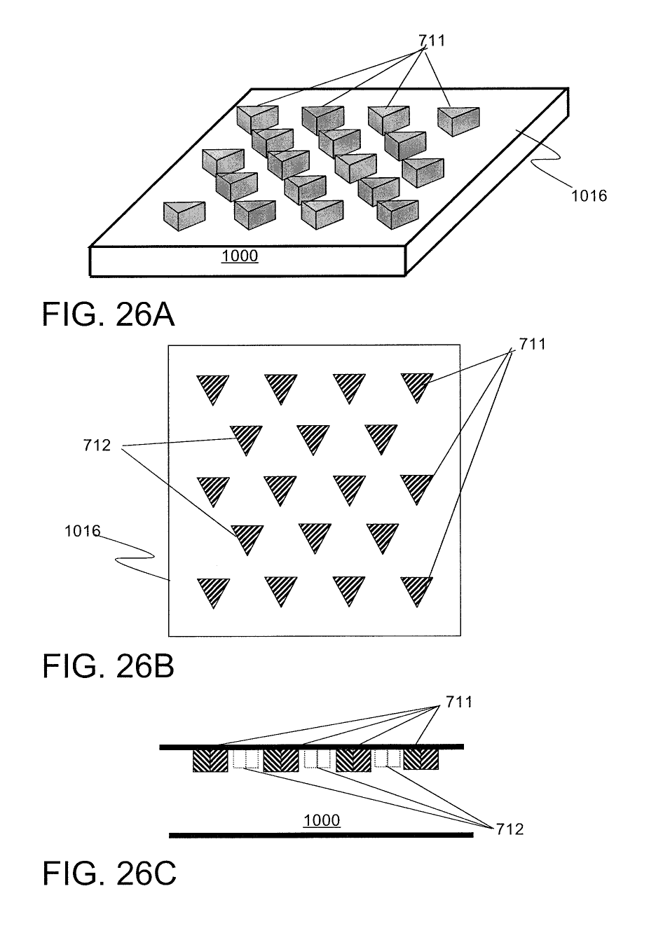

FIG. 26 illustrates a region 1016 of a target according to an embodiment of invention that comprises a closely packed array of microstructures 711 and 712 in the form of right triangular prisms comprising x-ray generating material. The closely packed array as shown is arranged as an embedded array in the surface of the substrate. FIG. 26A presents a perspective view of the eighteen embedded microstructures 711 and 712 in this example, while FIG. 26B illustrates a top down view of the same region, and FIG. 26C presents a side/cross-section view of the same region with depth perception.

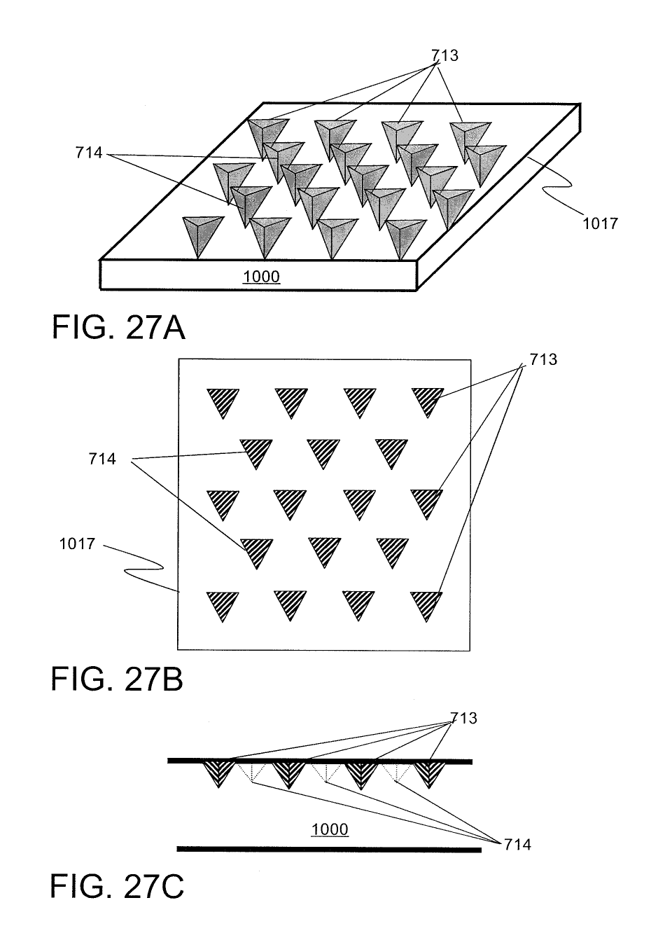

FIG. 27 illustrates a region 1017 of a target according to an embodiment of invention that comprises a closely packed array of microstructures 713 and 714 in the form of tetrahedral prisms comprising x-ray generating material, in which a single face is approximately flush with the surface of the substrate 1000. The closely packed array as shown is arranged as an embedded array in the surface of the substrate. FIG. 27A presents a perspective view of the eighteen embedded microstructures 713 and 714 in this embodiment, while FIG. 27B illustrates a top down view of the same region, and FIG. 27C presents a side/cross-section view of the same region with depth perception.

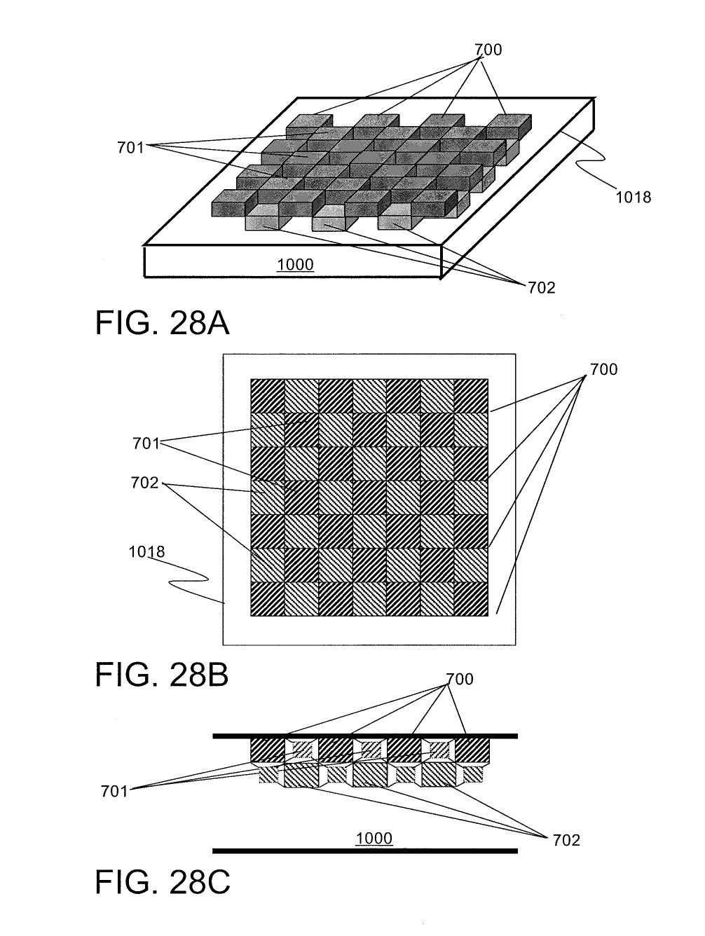

FIG. 28 illustrates a region 1018 of a target according to an embodiment of invention that comprises a combination of previously described microstructures 700, 701 and 702 in the form of right rectangular prisms comprising x-ray generating material. In this embodiment, the layer of microstructures 700 and 701 embedded near the surface forms a checkerboard pattern, as was illustrated in FIG. 23, while the structure also comprises a buried layer of microstructures 702 that are placed below the “gaps” in the upper checkerboard pattern. As in the previously described cases, the microstructures in the buried layer may be large enough to be in electrical contact with the microstructures 700 and 701 in the upper embedded layer, while in other embodiments, a distinct electrically conducting layer to carry charge away from the buried microstructures 702 may be fabricated to provide a path to ground. FIG. 28A presents a perspective view of the forty-eight embedded microstructures 700, 701, and 702 in this embodiment, while FIG. 28B illustrates a top down view of the same region, and FIG. 28C presents a side/cross-section view of the same region with depth perception.

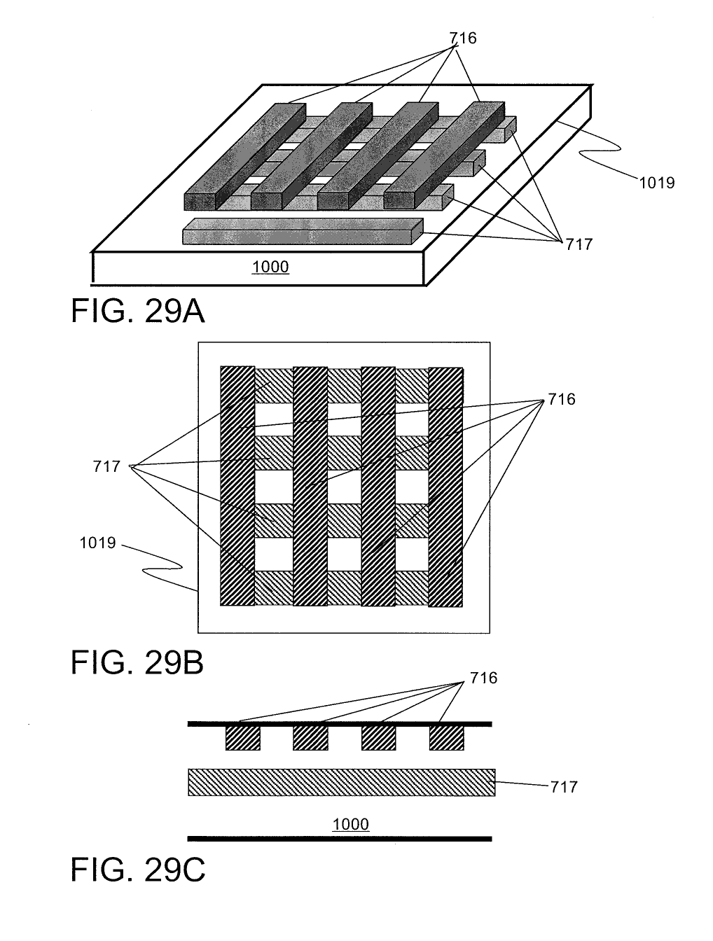

FIG. 29 illustrates a region 1019 of a target according to an embodiment of invention that comprises both embedded microstructures 716 and buried microstructures 717 in the form of long right rectangular prisms comprising x-ray generating material. In the embodiment as shown, for alternating layers, the long prisms are arranged to extend in directions orthogonal to each other, in a configuration that is often called a “stack-of-logs” configuration. As in the previously described cases, the microstructures 717 in the buried layer may be in electrical contact with the microstructures 716 in the upper embedded layer, while in other embodiments, a distinct electrically conducting layer to carry charge away from the buried microstructures 717 may be fabricated to provide a path to ground. FIG. 29A presents a perspective view of the microstructures 716 and 717 in this embodiment, while FIG. 29B illustrates a top down view of the same region, and FIG. 29C presents a side/cross-section view of the same region with depth perception.

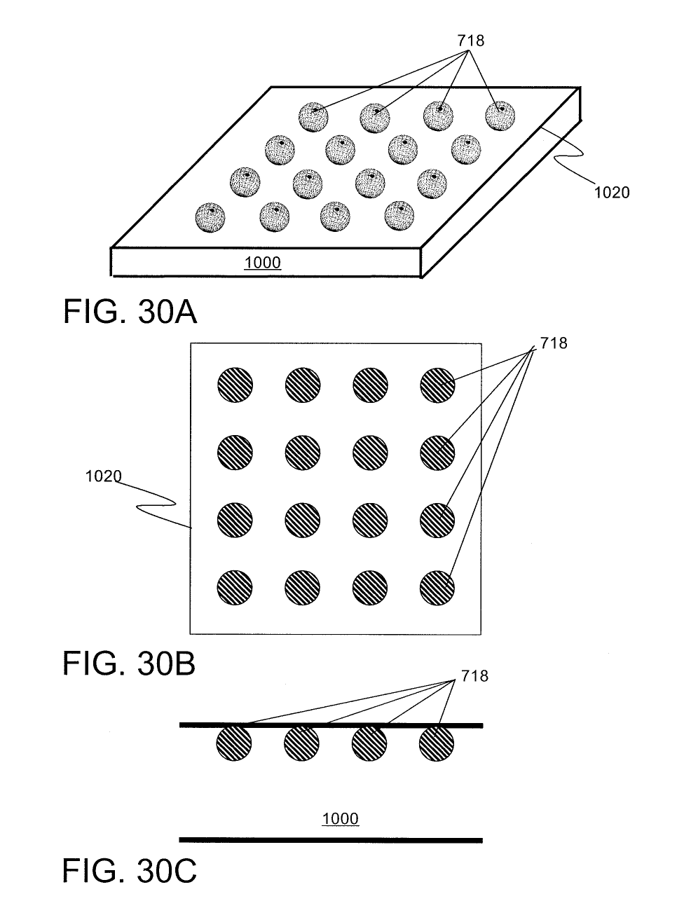

FIG. 30 illustrates a region 1020 of a target according to an embodiment of invention that comprises an array of microstructures 718 in the form of spheres comprising x-ray generating material. The array as shown is arranged as an embedded array in the surface of the substrate. FIG. 30A presents a perspective view of the sixteen embedded microstructures 704 in this embodiment, while FIG. 30B illustrates a top down view of the same region, and FIG. 30C presents a side/cross-section view of the same region.

Fabrication of a region of embedded spheres as illustrated in FIG. 30 may in some embodiments have a favorable mechanical rigidity or lower manufacturing cost, but the creation of a spherical cavity in the substrate into which material may be deposited may present process challenges. Therefore, in some embodiments, a hemispherical cavity may be created in the substrate, which is then filled with x-ray generating material, or pre-fabricated spheres may be deposited on the surface and encased with a deposited overcoat material.

As discussed earlier, although the various examples disclosed herein may be illustrated with ordered periodic or regular arrays of microstructures, the relative position, size and shape of the discrete microstructures need not be regular, periodic, or uniform. Arrangements of microstructures that have a distribution of sizes, with spacing between microstructures that can have a range of distances, may also be functional.

For some embodiments, various metrics to determine the size and distribution of the microstructures comprising x-ray generating material may be used. Microstructures may be designated to be a predetermined thickness D within the target, where, as discussed before, D may be selected to be a certain fraction of the electron penetration depth for a electrons of a given energy in a given x-ray generating material (such as, for example, 30% or 50%) or may be a range of allowed depths. Microstructures may be specified such that their lateral dimensions L and W do not exceed D by more than a specific factor (e.g. a factor of 2 or 3), and that any individual microstructure be no closer than a predetermined distance d to a neighboring microstructure. Alternatively, microstructures may be specified such that their lateral dimensions L and W do not exceed the x-ray attenuation length (the length at which the intensity of an x-ray beam of a specific energy falls off by a factor of 1/e), which will be different for different applications.

In the most general case, the region comprising microstructures may be specified by defining a volume fraction of the entire area to be exposed to electrons up to the thickness D that will comprise x-ray generating material. For example, if microstructures of tungsten (W) are to be used with 60 keV electrons, the penetration depth from Table II is 2.41 microns, and a value of D=1 micron would represent a thickness of 41% of the penetration depth. Defining a volume fraction of 50% for the initial layer of thickness D=1 μm could either be achieved by using, for example, the checkerboard array of FIG. 23, or by a more random distribution of microstructures of varying sizes and shapes as long as the volume fraction of x-ray generating material to substrate material was approximately 50% within the region of the target comprising microstructures and not including the surrounding target substrate. Such configurations may offer, for example, an advantage in terms of additional surface area for heat transfer.

The volume fraction for the x-ray generating region may also be set to varying values, depending on the electron energy, the x-ray generating material properties, and the substrate reabsorption properties. For some applications requiring specific characteristic lines, configurations with a lower volume fraction may be preferred. For other variations on the emission spectrum, such as those with a range of wavelengths, a higher volume fraction that increases the bremsstrahlung may be preferred. In general, volume fractions in the first layer of thickness D may be set to be between 15% and 85% for various applications.

Alternatively, in some embodiments, spherical microstructures of x-ray generating material may be prepared in advance, and then dispersed onto the surface of the substrate. A process that fixes the microstructures in place may be used, particularly if it is desired that the microstructures be positioned in a regular array (as was illustrated in FIG. 30). This may be followed by a deposition process that encases these spherical microstructures in a thermally conducting material. In some embodiments, this may be a material chosen only for its thermally conducting properties, while in other cases, the deposited material may be selected as a mixture of materials selected so that both thermal conductivity and electrical conductivity are beneficial, and the encasing material also serves as the electrically conducting layer that provides a path to ground.

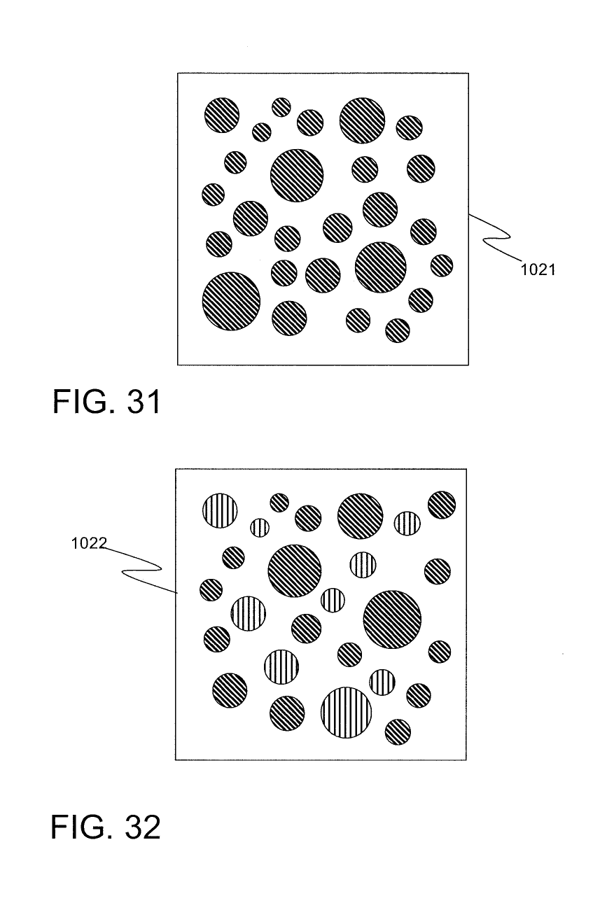

In another embodiment, the dispersal of microstructures comprising x-ray generating material need not be confined to uniform spheres, but may be a number or particles of various sizes and shapes. This is illustrated in FIG. 31, in which a region 1021 of a target according to the invention comprises non-uniform microstructures. Likewise, in a similar embodiment, a region 1022 of a target according to the invention may comprise microstructures not only of varying sizes and shapes, but microstructures of different material compositions as well, as illustrated in FIG. 32.

Up to this point, embodiments that are arranged in planar configurations have been presented. These are generally easier to implement, since equipment and process recipes for deposition, etching and other planar processing steps are well known from processing devices for microelectromechanical systems (MEMS) applications using planar diamond, and from processing silicon wafers for the semiconductor industry.

However, in some embodiments, a surface with additional properties in three dimensions (3-D) may be desired. As discussed previously, when the electron beam is larger than the electron penetration depth, the apparent x-ray source size and area is at minimum (and brightness maximized) when viewed parallel to surface, i.e. at a zero degree (0°) take-off angle. As a consequence, the apparent brightest of x-ray emission occurs when viewed at 0° take-off angle. The emission from within the x-ray generating material will accumulate as it propagates at 0° through the material.

However, with an extended target of substantially uniform material, the attenuation of x-rays between their points of origin inside the target as they propagate through the material to the surface increases with decreasing take-off angle, due to the longer distance traveled within the material, and often becomes largest at or near 0° take-off angle. Reabsorption may therefore counterbalance any increased brightness that viewing at near 0° achieves. The distance through which an x-ray beam will be reduced in intensity by 1/e is called the x-ray attenuation length, and therefore, a configuration in which the emitted x-rays pass through as little additional material as possible, with the distance selected to be related to the x-ray attenuation length, may be desired.

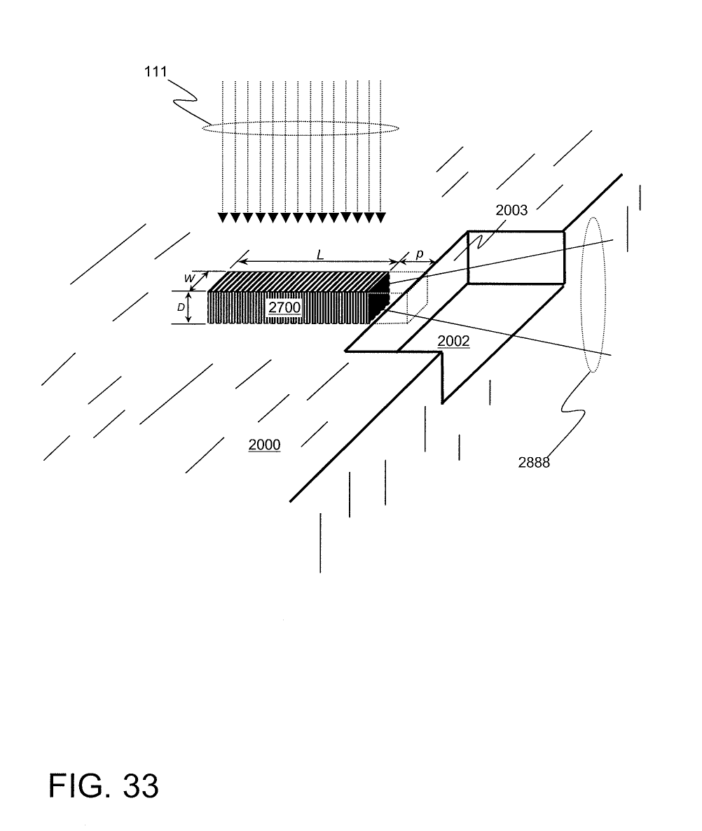

An illustration of one embodiment of a target is presented in FIG. 33. In FIG. 33, an x-ray generating region comprising a single microstructure 2700 is configured at or near a recessed edge 2003 of the substrate on a shelf 2002, similar to the situation illustrated in FIG. 10. The x-ray generating microstructure 2700 is in the shape of a rectangular bar of x-ray generating material, is embedded in a substrate 2000, and emits x-rays 2888 when bombarded with electrons 111.

The thickness of the bar D (along the surface normal of the target) is selected to be between one third and two thirds of the electron penetration depth of the x-ray generating material at the incident electron energy for optimal thermal performance. It may also be selected to obtain a desired x-ray source size in the vertical direction. The width of the bar W is selected to obtain a desired source size in the corresponding direction. As illustrated, W≈1.5D, but could be substantially smaller or larger, depending on the size of the source spot desired.

The length of the bar L as illustrated is L≈4D, but may be any dimension, and may typically be determined to be between ¼ to 3 times the x-ray attenuation length for the selected x-ray generating material. The distance between the edge of the shelf and the edge of the x-ray generating material p as illustrated is p≈W, but may be selected to be any value, from flush with the edge 2003 (p=0) to as much as 1 mm, depending on the x-ray reabsorption properties of the substrate material, the relative thermal properties, and the amount of heat expected to be generated when bombarded with electrons.

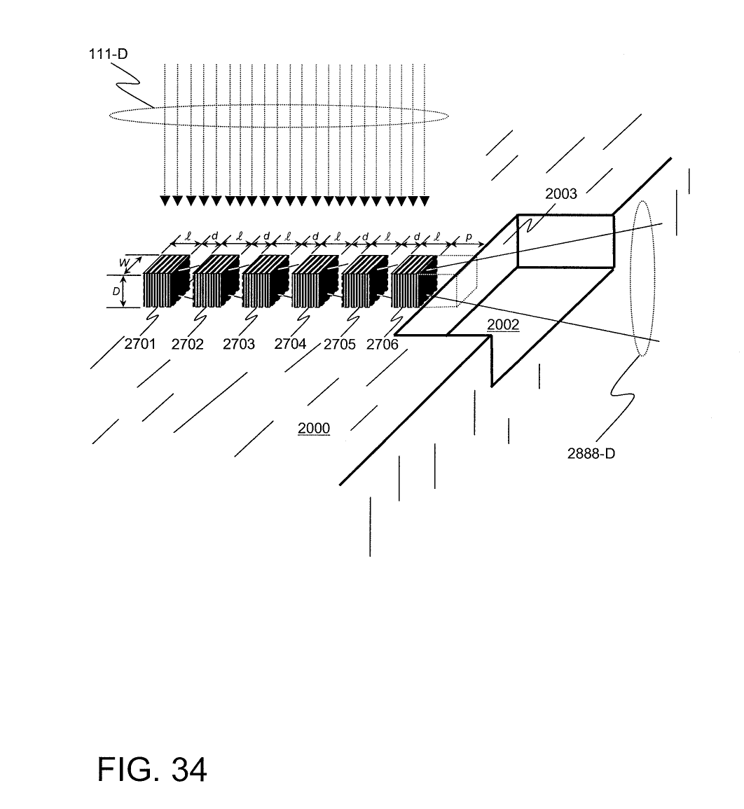

An illustration of an alternative embodiment of the invention is presented in FIG. 34. In this embodiment as illustrated, a target according to the invention comprising an x-ray generating region with six microstructures 2701, 2702, 2703, 2704, 2705, 2706 is configured at or near a recessed edge 2003 of the substrate on a shelf 2002, similar to the situation illustrated in FIG. 10 and FIG. 33. The x-ray generating microstructures 2701, 2702, 2703, 2704, 2705, 2706 are arranged in a linear array of x-ray generating right rectangular prisms embedded in a substrate 2000, and emit x-rays 2888-D when bombarded with electrons 111.

In this embodiment, the total volume of x-ray generating material is the same as in the previous illustration of FIG. 33. The thickness of the bar D (along the surface normal of the target) is selected to be between one third and two thirds of the electron penetration depth of the x-ray generating material at the incident electron energy for optimal thermal performance, as in the case shown in FIG. 33. The width of the bar W is selected to obtain a desired source size in the corresponding direction and as illustrated, W≈1.5 D, as in the case shown in FIG. 33. As discussed previously, it could also be substantially smaller or larger, depending on the size of the source spot desired.

However, the single bar 2700 of length L as illustrated in FIG. 33 has been replaced with 6 sub-bars 2701, 2702, 2703, 2704, 2705, 2706 each of length 1=L/6. Although the volume of x-ray generation (when bombarded with the same electron density) will be the same, each sub-bar now has five faces transferring heat into the substrate, increasing the heat transfer away from the x-ray generating sub-bars 2701-2706 and into the substrate. As illustrated, the separation between the sub-bars is a distance d≈1, although larger or smaller dimensions may also be used, depending on the amount of x-rays absorbed by the substrate and the relative thermal gradients that may be achieved between the specific materials of the x-ray generating microstructures 2701-2706 and the substrate 2000.

Likewise, the distance between the edge of the shelf and the edge of the x-ray generating material p as illustrated is p≈W, but may be selected to be any value, from flush with the edge 2003 (p=0) to as much as 1 mm, depending on the x-ray reabsorption properties of the substrate material, the relative thermal properties, and the amount of heat expected to be generated when bombarded with electrons.

For a configuration such as shown in FIG. 34, the total length of the x-ray generating sub-bars will commonly be about twice the linear attenuation length for x-rays in the x-ray generating material, but can be selected from half to more than 3 times that distance. Likewise, the thickness of the bar (along the surface normal of the target) D was selected to be equal to one third to two thirds of the electron penetration depth of the x-ray generating material at the incident electron energy for optimal thermal performance, but it can be substantially larger. It may also be selected to obtain a desired x-ray source size in that direction which is approximately equal.

The bars as shown may be embedded in the substrate (as shown), but if the thermal load generated in the x-ray generating material is not too large, they may also be placed on top of the substrate.

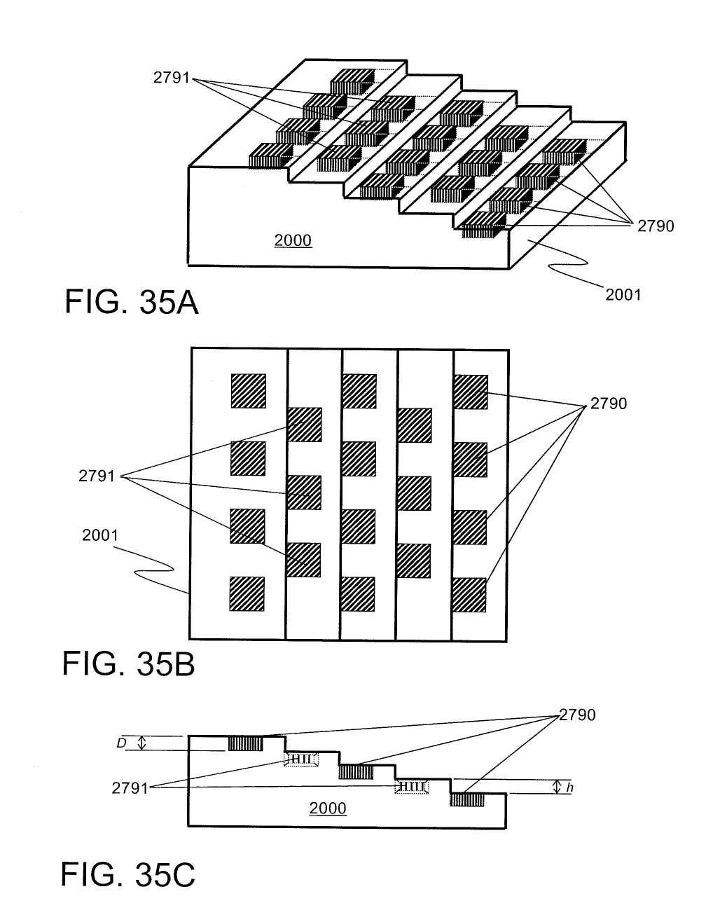

An illustration of another embodiment of the invention is presented in FIG. 35, which shows a region 2001 of a target according to an embodiment of invention with an array of microstructures 2790 and 2791 comprising x-ray generating material having a thickness D. The array as shown is a modified checkerboard pattern of right rectangular prisms, but other configurations and arrays of microstructures may be used as well.

As in other embodiments, these microstructures 2790 and 2791 are embedded in the surface of the substrate. However, the surface of the substrate comprises a predetermined non-planar topography, and in this particular case, a plurality of steps along the surface normal of the substrate 2000. As illustrated, the height of each step is h≈D, but the step height may be selected to be between 1× and 3× the thickness of the microstructures. The total height of all the steps may be selected to be equal or less than the desired x-ray source size along the vertical (thickness) direction.

The total width of the microstructured region may be equal to the desired x-ray source size in the corresponding direction. The overall appearance resembles a staircase of x-ray sources. FIG. 35A presents a perspective view of the eighteen embedded microstructures 2790 and 2791 in this embodiment, while FIG. 35B illustrates a top down view of the same region, and FIG. 35C presents a side/cross-section view of the same region. An electrically conductive layer may be coated on the top of the staircase structures when the substrate is beryllium, diamond, sapphire, silicon, or silicon carbide.

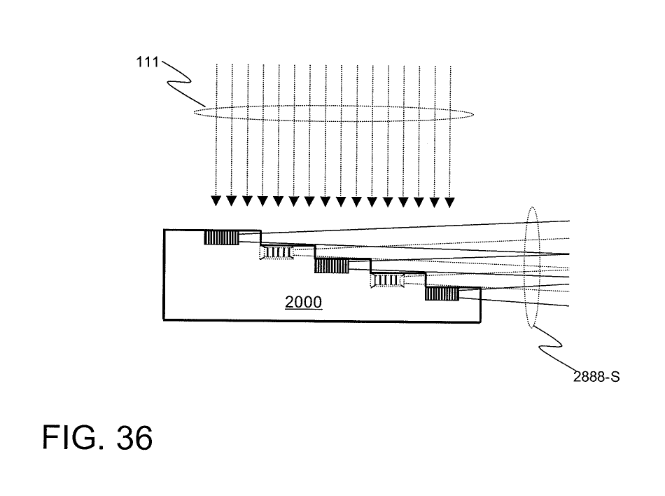

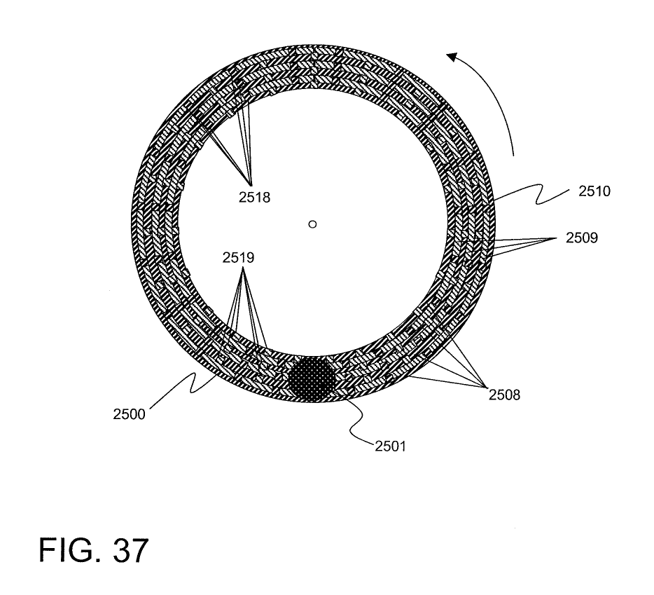

FIG. 36 illustrates the x-ray emission 888-S from the staircase embodiment of FIG. 35C when bombarded by electrons 111. As in the other embodiments, the prisms of x-ray generating material heat up when electrons collide with them, and because each of the prisms of x-ray generating material has five sides in thermal contact with the substrate 2000, conduction of heat away from the x-ray material is still larger than a configuration in which the x-ray material is deposited on the surface. However, to one side, the emission is of x-rays unattenuated by absorption from other neighboring prisms and negligibly attenuated by neighboring substrate material.

The brightness of x-rays from each prism will therefore be increased, especially when compared to the x-ray emission from the embodiment of, for example, FIG. 23, which also illustrates a number of prisms 700 and 701 of x-ray generating material arranged in a checkerboard pattern. In the configuration of FIG. 23, each prism is embedded in the substrate, therefore having five surfaces in thermal contact with the substrate 1000, but the emission to the side at 0° will be attenuated by both the prisms of the neighboring columns and the substrate material.

Such an embodiment comprising a target with topography may be manufactured by first preparing a substrate with topography, and then embedding the prisms of x-ray material following the fabrication processes for the previously described planar substrates. Alternatively, the initial steps that create cavities to be filled with x-ray material may be enhanced to create the staircase topography structure in an initially flat substrate.

In either case, additional alignment steps, such as those known to those skilled in the art of planar processing, may be employed if overlay of the embedded prisms with a particular feature of topography is desired.

Microstrutures may be embedded with some distance to the edges of the staircase, as illustrated in FIGS. 35 and 36, or flush with as edge (as was shown in FIG. 9). A determination of which configuration is appropriate for a specific application may depend on the exact properties of the x-ray generation material and substrate material, so that, for example, the additional brightness achieved with increased electron current enabled by the thermal transfer through five vs. four surfaces may be compared with the additional brightness achieved with free space emission vs. reabsorption through a section of substrate material. The additional costs associated with the alignment and overlay steps, as well as the multiple processing steps that may be needed to pattern multiple prisms on multiple layers, may need to be considered in comparison to the increased brightness achievable.

The embodiments described so far describe a variety of x-ray target configurations that comprise a plurality of microstructures comprising x-ray material that can be used as targets in x-ray sources to generate x-rays with increased brightness. These target configurations have been described as being bombarded with electrons and emitting x-rays, but may be used as the static x-ray target in an otherwise conventional source, replacing either the target 01 from the transmission x-ray source 08 of FIG. 1, or the target 100 from the reflective x-ray source 80 of FIG. 2, with a target according to the invention.

It is also possible that the embodiments as described could be equally well applied to a moving x-ray target, replacing, for example, the target 500 from the rotating anode x-ray source 80 of FIG. 6 with a target according to the invention.

FIG. 37 illustrates an embodiment of the invention configured as a rotating anode 2500. On the outer annulus of the rotating anode 2500, a plurality of x-ray generating materials have been formed, and may be Ruined by any of the processes previously described. In the embodiment as illustrated in FIG. 37, two distinct materials are illustrated, each with various microstructures in the form of either annular rings 2508 and 2509 or square structures 2518 and 2519.

As in the conventional rotating anode, electrons bombard the target anode 2500 at the edge, which may be beveled, just as a conventional rotating anode is beveled, and the source of the electron beam directs the electron beam onto the beveled edge 2510 of the target anode 2500, generating x-rays from a target spot 2501. As the target spot 2501 generates x-rays, it heats up, but as the target anode 2500 rotates, the heated spot moves away from the target spot 2501, and the electron beam now irradiates a cooler portion of the target anode 2500. The hot spot has the time of one rotation to cool before becoming heated again when it passes through the hot spot 2501. By continuously rotating the target anode 2500, a single spot never becomes too hot, yet a continuous source of x-rays can be provided.

As in the previously described rotating anode system, additional cooling channels may be provided in the rotating anode to further cool the anode, allowing bombardment with electrons at higher voltages or with higher current densities to make a brighter x-ray source. However, if the target material in the rotating anode uses a plurality of microstructures according to the invention disclosed herein, the improved thermal properties may allow higher electron power loading. This enables an x-ray source of higher brightness, because the electron energy and current may be increased once the additional heat load can be accommodated. Alternatively, the thermal benefits may be used to enable a rotating anode source of the same brightness, but with components that are easier to engineer, such as lower voltage, lower current, or slower anode rotation speed.

### 4. Fabrication Processes

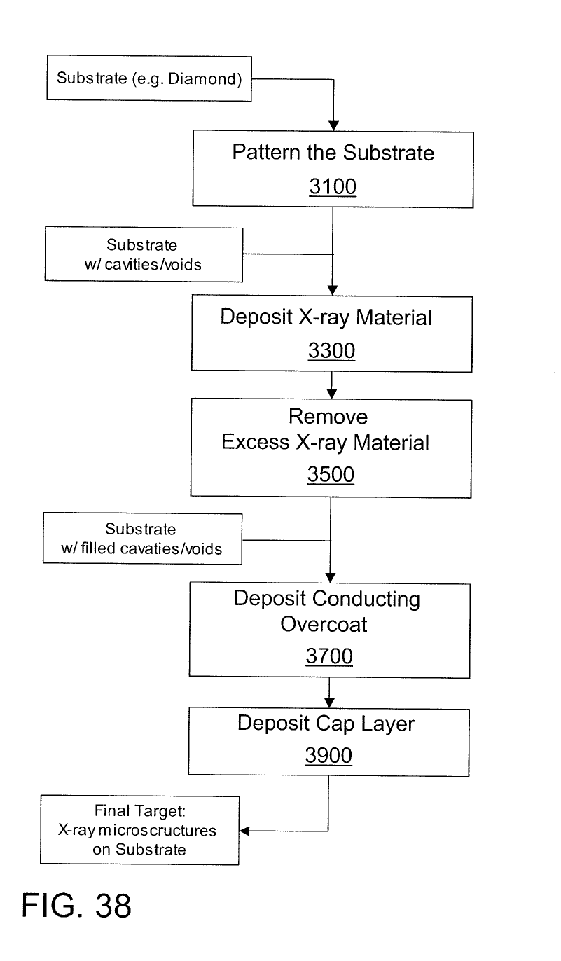

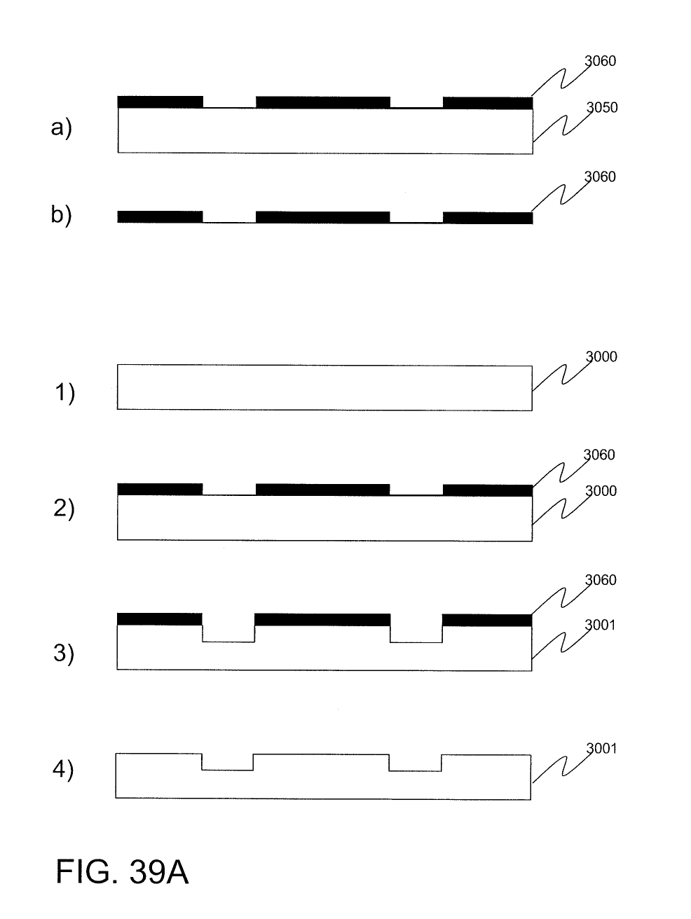

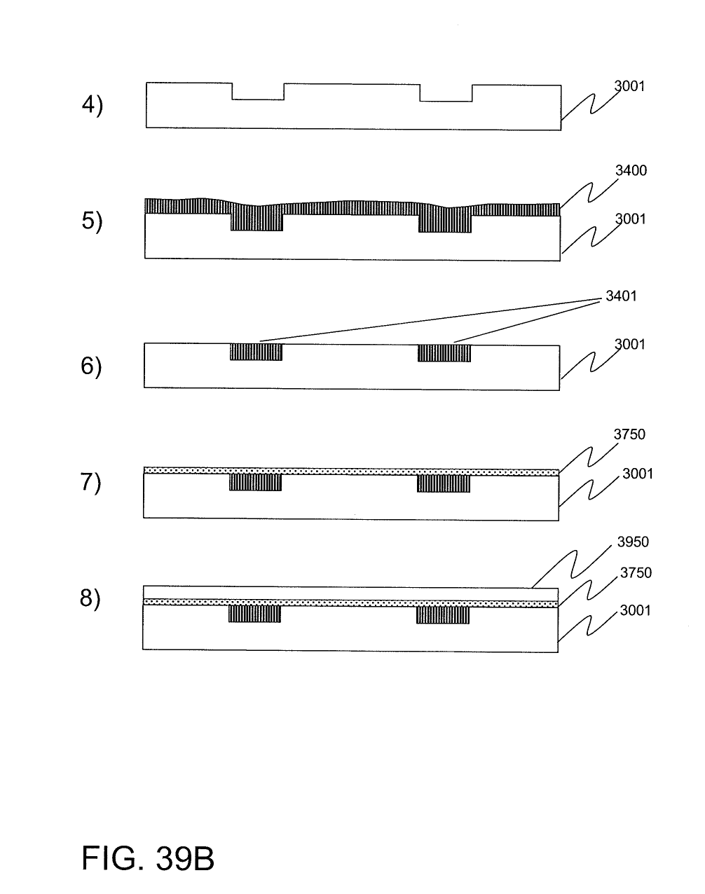

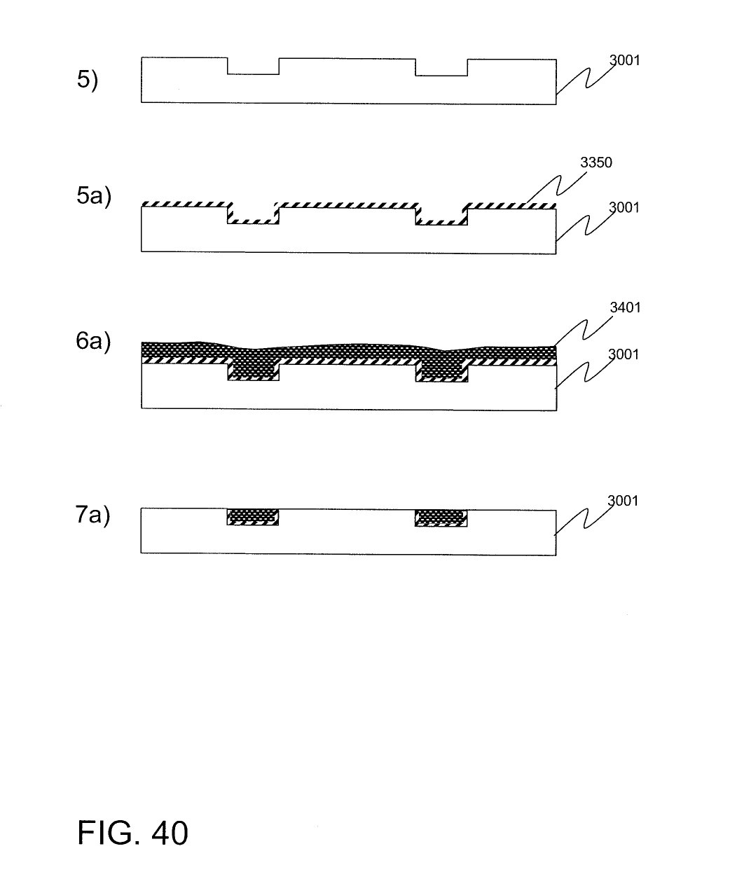

The methods for fabricating the targets according to the invention involve a number of steps that are outlined in the flow chart of FIG. 38, and the cross-section diagrams of FIGS. 39-40.

4.1. Selecting a Substrate.

In the initial step, a substrate 3000 of a suitable material is selected. In FIG. 39A, this is denoted by the step designated “1)”. As discussed above, this will typically be a material selected for various physical and thermal properties, and in particular, low mass density, low Z, and a high thermal conductivity. Several candidates for substrate materials are listed in Table I, several with high thermal conductivity (i.e. materials with thermal conductivity greater than 100 W/(m° C.)). Among these materials, diamond stands out as a potential substrate. At room temperature, the thermal conductivity is ˜2200 W/(m ° C.), one of the highest values known for any material. At lower temperatures, approximately −120° C., this value can increase to be almost three times higher.

Wafers of CVD grown diamond up to 120 mm in diameter and with diamond coatings up to 2 mm thick may be may be purchased from Diamond Materials GmbH of Freiburg, Germany. Substrates of silicon coated with diamond or diamond on insulator (DOI) may also be purchased from, for example, Advanced Diamond Technologies, Inc. of Romeoville, Ill. or sp3 Diamond Technologies of Santa Clara, Calif. Diamond-like carbon (DLC) films such as those manufactured by Richter Precision, Inc. of East Petersburg, Pa. may also be useful as substrate materials.

Beryllium may also be a candidate for a substrate material. With a low atomic number (Z=4), beryllium is very lightweight and is especially transparent to x-rays, and therefore less likely to be a source of continuum x-rays that might interfere with the x-ray emission from the plurality of microstructures embedded within the substrate. Beryllium wafers may be commercially purchased from, for example, American Elements, Inc. of Los Angeles, Calif., and Atomergic Chemetals Corporation of Farmingdale, N.Y.

Other materials that may be suitable as substrates are graphite, silicon, boron nitride, gallium nitride, silicon carbide and sapphire. Other suitable materials may also be known to those skilled in the art.

4.2. Patterning the Substrate.

Once a substrate is selected, the next step 3100, as shown in FIG. 38, is to pattern the substrate 3001, as shown in FIG. 39A. There are several known approaches to patterning diamond for MEMS applications, nanoimprint lithography, and other processes. [See, for example, H. Masuda et al., “Fabrication of Through-Hole Diamond Membranes by Plasma Etching Using Anodic Porous Alumina Mask”, Electrochemical and Solid-State Letters, vol. 4(11), pp. G101-G103 (2001); Y. Ando et al. “Smooth and high-rate reactive ion etching of diamond”, Diamond and Related Materials vol. 11 (2002) pp. 824-827 (2002); X. D. Wang et al. “Precise patterning of diamond films for MEMS application”, J. Material Processing Technology vol. 127, pp. 230-233 (2002); and J. Taniguchi et al., “Diamond Nanoimprint Lithography”, Nanotechnology vol. 13 pp. 592-596 (2002), and D. S. Hwang, T. Saito and N. Fujimori, “New etching process for device fabrication using diamond”, Diamond & Related Materials vol. 13, pp. 2207-2210 (2004).]

In the process cited above by Masuda et al., a polished polycrystalline diamond film ˜3 mm thick is patterned using a porous alumina mask. The mask is prepared in advance using a silicon carbide mold to texture an aluminum surface, which is subsequently oxidized through an anodization process. The alumina film so formed has pores with positions determined by the texture on the SiC mold. The film is then removed from its aluminum substrate and transferred to the diamond surface. The diamond is then subjected to an oxygen reactive ion etch process, in which the porous alumina film acts as a mask.

Representative steps for this process step 3100 are illustrated with the corresponding steps in FIG. 39A denoted by “a)”, “b)”, “2)”, “3)” and “4)”.

In FIG. 39A step “a)”, a mask 3060 is formed and patterned on a substrate 3050. The mask may be, for example, alumina patterned on an aluminum substrate. In step “b)”, the mask is removed. In step “2)”, the mask 3060 is attached to the substrate 3000. In step “3)”, the mask and substrate undergo a pattern transfer step, such as an oxygen reactive ion etch (RIE), creating the patterned substrate 3001 from the initial substrate 3000. In step “4)”, the mask 3060 is removed, and leaving the patterned substrate 3001.

Alternatively, the substrate may be patterned using conventional lithographic processes. These may include coating the substrate with a photoresist, such as HSQ, and exposing the resist using electron beams or ultraviolet photons in a pattern that represents the desired structure to be formed on the wafer. The resist is then developed to remove the exposed regions, laying the substrate bare. The substrate and patterned resist combination are then processed with a suitable etching process (such as a reactive ion etch (RIE) with oxygen gas) that transfers the pattern in the resist into the substrate. Once this is completed, the excess resist is removed, leaving a patterned substrate essentially the same as the patterned substrate 3001 designated by step “4)” in FIGS. 39A and 39B.

In a variation on the lithographic patterning process described above, the substrate may be coated with a specially selected material that serves as a hard mask for patterning the substrate. The steps in this case are: coating of a hard mask onto the substrate, coating resist onto the hard mask, patterning the resist with either electron or optical exposure, developing the resist, transferring the pattern from the resist into the hard mask, and transferring the pattern from the hard mask into the substrate, leaving a patterned substrate essentially the same as the patterned substrate 3001 designated by step “4)” in FIGS. 39A and 39B. Such lithographic processes and their variations may be well known to those skilled in the art.

In other alternatives to the lithographic patterning processes discussed above, the substrate may also be directly ion milled using a machine such as a focused ion beam. Other techniques, such as laser etching, may also be used to pattern the substrate.

4.3. Embedding the X-Ray Material.

Once a substrate has been patterned, the next step is the deposition of a material that can produce x-rays of desired characteristics into the patterned cavities 3300. This may be through any number of well-known deposition techniques, depending on the material, including chemical vapor deposition (CVD), sputtering, electroplating, mechanical stamping, or others that will be known to those skilled in the art. Various materials may be selected for use as x-ray generating materials, including aluminum, titanium, vanadium, chromium, manganese, iron, cobalt, nickel, copper, gallium, zinc, yttrium, zirconium, molybdenum, niobium, ruthenium, rhenium, rhodium, palladium, silver, tin, iridium, tantalum, tungsten, indium, cesium, barium, gold, platinum, lead and combinations and alloys thereof.

Representative steps for this process step 3300 are illustrated with the corresponding steps in FIG. 39B denoted by “5)”.

Once the x-ray material has been deposited, there is typically an excess of material on the substrate. The following step of polishing 3500 with either a mechanical/abrasive polishing process, or a chemical-mechanical polishing (CMP) process, removes the excess material, leaving behind the cavities in the patterned substrate 3001 now filled with discrete microstructures 3401 of x-ray material, as illustrated with the corresponding step in FIG. 39B denoted by “6)”.

4.4. An Adhesive Alternative

Some materials, when used in combination with certain substrates, may form an interface layer that provides a good bond between the two. For example, for a selected x-ray material such as tungsten, CVD deposition of tungsten material 3400 onto a patterned diamond substrate 3001 can be adequate to fill the cavities in the diamond, with the tungsten forming a strong carbide bond in the boundary between the tungsten and the carbon. However, for other materials, such as copper, the use of an adhesive layer, such as the deposition of a 10 nm thick layer of titanium (Ti) or chromium (Cr) between the copper and a diamond substrate may be preferred to improve the mechanical integrity of the anode, both by increasing the adhesion between the two materials, and also in some cases by preventing diffusion of material from one region into the other.

Representative steps for this process step are illustrated with the corresponding steps in FIG. 40 denoted by “5)”, “5a)”, “6a)” and “7a)”.

In FIG. 40 starting with the patterned substrate 3001, step “5a)” illustrates the deposition of a suitable adhesion layer 3350 onto the patterned substrate 3001. Typical adhesion layers 3350 may be layers of chromium (Cr) or titanium (Ti) when used, for example, with copper (Cu) as the x-ray material. Other materials may include carbide alloys of the target material, such as copper carbide (CuC) for copper or aluminum carbide (AlC) for aluminum. Additionally, other materials with good adhesion to both materials known to those skilled in the art may be used. As an example, molybdenum is often used as a barrier layer for copper. Furthermore, multiple layers of materials, such as titanium carbide (TiC) bilayers or chromium carbide (CrC) bilayers may be used as adhesion layers. The thickness of the adhesion layer may vary with the selection of x-ray material and substrate material, but will typically be on the order of 10 nm thick. Once deposited, the deposition step may be followed by a carbonization step, to form a carbide compound with the substrate. In other embodiments, a carbide material may be directly deposited to provide an adhesion layer.

4.5. Overcoats.

Once a substrate has been patterned and the cavities filled to create microstructures of x-ray material, the next step is the deposition of a conducting layer, so that electrons impinging on the x-ray material will have a path to ground.

A representative illustration for this process step 3700 is shown with the corresponding result in FIG. 39B denoted by “7)”.

The deposited material 3750 may be any one of a number of electrically conducting materials, such as beryllium (Be), aluminum (Al), chromium (Cr), titanium (Ti), silver (Ag), gold (Au), copper (Cu), or carbon materials such as graphite or carbon nanotubes. The material may be as thin as 5 nm or as thick as 100 nm, and in some circumstances, such as if there are larger topography variations in the substrate with filled cavities, the material may be as thick as 500 nm.

The deposition techniques may be any number of a variety of deposition techniques, including but not limited to chemical vapor deposition (CVD), sputtering, electroplating, mechanical stamping, or others that will be known to those skilled in the art.

Once the electrically conducting layer has been deposited, a final protective overcoat, or cap layer, may also be deposited.

A representative illustration for this process step 3900 is shown with the corresponding result in FIG. 39B denoted by “8)”.

The deposited material 3950 may be any one of a number of materials, but may be typically selected to be the same material used for the substrate, such as diamond (C) diamond-like carbon (DLC), or beryllium (Be), or another materials, such as silicon carbide (SiC), chromium (Cr), molybdenum (Mo), rhodium (Rh) and palladium (Pd). The material may be as thin as 100 nm, or may be as thick as 50 μm.

The deposition techniques may be any number of a variety of deposition techniques, including but not limited to chemical vapor deposition (CVD), sputtering, electroplating, mechanical stamping, or others that will be known to those skilled in the art.

To have good adhesion to the layers below, the deposition of the cap layer may be preceded by the deposition of an adhesion layer, such as a titanium carbide (TiC) to form a seed layer for the growth of diamond. The deposition may be very thin, perhaps between 1 and 5 nm, to provide this seed layer.

4.6. Process Combinations.

Once these steps have been completed, the final object, denoted with “8)” in FIG. 39B, comprises a substrate comprising a plurality of microstructures of x-ray generating material suitable for use as a target in an x-ray source.

Although certain processes steps have been described in certain sequences, it should be known that certain steps may be executed in a different order or combined with each other to achieve a similar result.

For example, the electrically conducting layer has been described as occurring before the deposition of a cap layer, but a layer that combines these functions (i.e. an electrically conducting cap layer) such as that illustrated in FIG. 19. Likewise, some of the process steps may be repeated to deposit multiple layers of target materials, as was illustrated in FIG. 18.

Furthermore, multiple layers of microstructures, as were illustrated in FIG. 21, may be created by repeating process steps (or portions thereof) as described in this section.

### 5. Limitations and Extensions

With this application, several embodiments of the invention, including the best mode contemplated by the inventors, have been disclosed. It will be recognized that, while specific embodiments may be presented, elements discussed in detail only for some embodiments may also be applied to others.

While specific materials, designs, configurations and fabrication steps have been set forth to describe this invention and the preferred embodiments, such descriptions are not intended to be limiting. Modifications and changes may be apparent to those skilled in the art, and it is intended that this invention be limited only by the scope of the appended claims.

All elements, parts and steps described herein are preferably included. It is to be understood that any of these elements, parts and steps may be replaced by other elements, parts and steps or deleted altogether as will be obvious to those skilled in the art.

Broadly, this writing discloses at least the following:

Targets for generating x-rays using electron beams, and their method of fabrication. The targets comprise a number of microstructures fabricated from an x-ray target material arranged in close thermal contact with a substrate such that the heat is more efficiently drawn out of the x-ray target material. This in turn allows irradiation of the x-ray generating substance with higher electron density or higher energy electrons, which leads to greater x-ray brightness, without inducing damage or melting.

The microstructures may comprise conventional x-ray target materials (such as tungsten) that are patterned at micron-scale dimensions on a thermally conducting substrate, such as diamond. The microstructures may have any number of geometric shapes to best generate x-rays of high brightness and efficiently disperse heat.

In some embodiments, the target comprising microstructures may be incorporated into a rotating anode geometry, to enhance x-ray generation in such systems.

This writing also discloses the following concepts:
Concept 1. An x-ray target comprising:
   a substrate comprising a first selected material; and
   a plurality of discrete structures
      comprising a second material selected for its x-ray generation properties;
   in which each of the plurality of discrete structures
      is in thermal contact with the substrate; and
   in which at least one of the discrete structures
      has a thickness of less than 10 microns, and
      each lateral dimensions of said at least one of the discrete structures
      is less than 50 microns.
Concept 2. The x-ray target of claim 1, in which
   the plurality of discrete structures are embedded into the surface of the substrate.
Concept 3. The x-ray target of Concept 1 or 2, in which
   the surface of the substrate is a planar surface.
Concept 4. The x-ray target of Concept 1 or 2, in which
   the surface of the substrate comprises a predetermined non-planar topography.
Concept 5. The x-ray target of Concept 4, in which
   the topography comprises at least one step.
Concept 6. The x-ray target of any one of Concepts 1-5, in which
   at least one of the plurality of discrete structures
      is positioned within 1 mm from an edge of the substrate.
Concept 7. The x-ray target of any one of Concepts 1-6, in which
   the plurality of discrete structures are arranged in a periodic pattern.
Concept 8. The x-ray target of any one of Concepts 1-7, in which
   the plurality of discrete structures are arranged in a regular array.
Concept 9. The x-ray target of Concepts 1, 7 or 8, in which
   the plurality of discrete structures are arranged in a linear array.
Concept 10. The x-ray target of any one of Concepts 1-9, in which
   the plurality of discrete structures are fabricated to have similar shapes.
Concept 11. The x-ray target of Concept 10, in which
   the similar shapes are selected from the group consisting of
   regular prisms, right rectangular prisms, cubes, triangular prisms, trapezoidal prisms, pyramids, tetrahedra, cylinders, spheres, ovoids, and barrel-shapes.
Concept 12. The x-ray target of any one of the preceding Concepts 1-11, further comprising:
   a third electrically conducting material
      in electrical contact with the discrete structures.
Concept 13. The x-ray target of Concepts 1 or 12, further comprising:
   an overcoat comprising a fourth thermally conducting material.
Concept 14. The x-ray target of any one of the preceding Concepts 1-13, in which
   the first selected material is selected from the group consisting of
   beryllium, diamond, graphite, silicon, boron nitride, silicon carbide, sapphire and diamond-like carbon.
Concept 15. The x-ray target of any one of the preceding Concepts 1-14, in which
   the second material is selected from the group consisting of:
   aluminum, titanium, vanadium, chromium, manganese, iron, cobalt, nickel, copper, gallium, zinc, yttrium, zirconium, molybdenum, niobium, ruthenium, rhodium, palladium, silver, tin, iridium, tantalum, tungsten, indium, cesium, barium, gold, platinum, lead and combinations and alloys thereof.
Concept 16. The x-ray target of Concept 12, in which
   the third material is selected from the group consisting of:
   beryllium, aluminum, chromium, titanium, silver, gold, copper and carbon.
Concept 17. The x-ray target of Concept 16, in which
   the form of carbon is selected from the group consisting of graphite and carbon nanotubes.
Concept 18. The x-ray target of Concept 13, in which
   the fourth material is selected from the group consisting of:
   diamond, diamond-like carbon, beryllium, silicon carbide, chromium, molybdenum, rhodium and palladium.
Concept 19. The x-ray target of any one of the preceding Concepts 1-18, in which
   the substrate additionally comprises at least one cooling channel
   designed for the flow of a cooling fluid through the substrate.
Concept 20. The x-ray target of any one of the preceding Concepts 1-19, in which
   the substrate is mounted onto an additional heat sink.
Concept 21. The x-ray target of Concept 20 ex14, in which
   the additional heat sink comprises a thermoelectric cooler.
Concept 22. A method for manufacturing an x-ray target, comprising:
   patterning a substrate comprising a first selected material;
   depositing a second material selected for its x-ray generation properties
      into portions of the patterned substrate
   such that a plurality of discrete structures
      are created that are in thermal contact with the substrate; and
   such that at least one of the discrete structures
      has a thickness of less than 10 microns, and
      has each lateral dimension be less than 50 microns.
Concept 23. The method of Concept 22, in which the step of patterning the substrate comprises:
   attaching a pre-patterned layer to the substrate; and
   etching the substrate.
Concept 24. The method of Concept 23, in which
   the step of etching the substrate comprises
   using a reactive ion etch.
Concept 25. The method of Concept 22, in which the step of patterning the substrate comprises:
   coating the substrate with a resist;
   patterning the resist using a lithographic process;
   etching the substrate; and
   removing the resist.
Concept 26. The method of Concept 25, in which
   the step of etching the substrate comprises
   using a reactive ion etch.
Concept 27. The method of Concept 22, in which the step of patterning the substrate comprises:
   coating the substrate with a hard mask material,
   coating the substrate with a resist;
   patterning the resist using a lithographic process;
   etching the hard mask;
   removing the resist; and
   etching the substrate.
Concept 28. The method of Concept 27, in which
   the step of etching the substrate comprises
   using a reactive ion etch.
Concept 29. The method of any one of Concepts 22-28, additionally comprising:
   depositing an adhesion layer onto the patterned substrate before the deposition of the second material.
Concept 30. The method of any one of Concepts 22-29, additionally comprising:
   polishing the second material after it has been deposited
   to remove excess material.
Concept 31. The method of any one of Concepts 22-30, additionally comprising:
   depositing a third layer of conducting material
   onto the patterned substrate with discrete structures.
Concept 32. The method of Concept 31, additionally comprising:
   creating a fourth layer of thermally conducting material
   on the third layer of conducting material.
Concept 33. The method of any one of Concepts 22-32, in which
   the first selected material is selected from the group consisting of
   beryllium, diamond, graphite, silicon, boron nitride, silicon carbide, sapphire and diamond-like carbon.
Concept 34. The method of any one of Concepts 22-33, in which
   the second material is selected from the group consisting of:
   aluminum, titanium, vanadium, chromium, manganese, iron, cobalt, nickel, copper, gallium, zinc, yttrium, zirconium, molybdenum, niobium, ruthenium, rhenium, rhodium, palladium, silver, tin, iridium, tantalum, tungsten, indium, cesium, barium, gold, platinum, lead and combinations and alloys thereof.
Concept 35. The method of Concept 31, in which
   the third material is selected from the group consisting of:
   beryllium, aluminum, chromium, titanium, silver, gold, copper and carbon.
Concept 36. The x-ray target of Concept 35, in which
   the form of carbon is selected from the group
   consisting of graphite and carbon nanotubes.
Concept 37. The method of Concept 32, in which
   the fourth material is selected from the group consisting of:
   diamond, diamond-like carbon, beryllium, silicon carbide, chromium, molybdenum, rhodium and palladium.
Concept 38. The method of any one of Concepts 22-37, additionally comprising:
   creating a cooling channel in the substrate.
Concept 39. The method of any one of Concepts 22-38, additionally comprising:
   mounting the substrate on a heat sink.
Concept 40. The method of Concept 39, in which:
   the heat sink comprises a thermoelectric cooler.
Concept 41. An x-ray target, comprising:
   a substrate comprising a first selected material;
   one or more discrete structures embedded in the substrate;
   a third electrically conducting material
      in electrical contact with one or more of the discrete structures; and
   an overcoat comprising a fourth thermally conducting material;
   in which each of the one or more discrete structures
      comprises a second material selected for its x-ray generation properties; and
   in which each of the one or more discrete structures
      is in thermal contact with the substrate; and
   in which at least one of the discrete structures
      has a thickness of less than 10 microns and
      lateral dimensions less than 50 microns.
Concept 42. The x-ray target of Concept 41, in which
   the first selected material comprises diamond;
   the second selected material is selected from the group consisting of copper, molybdenum and tungsten;
   the third selected material comprises aluminum; and
   the fourth thermally conducting material comprises diamond.

What is claimed is:

1. An x-ray target comprising:
a substrate comprising a first selected material; and
a plurality of discrete structures
comprising a second material selected for its x-ray generation properties;
in which each of the plurality of discrete structures
is in thermal contact with the substrate; and
in which at least one of the discrete structures
has a thickness of less than 10 microns, and
each lateral dimensions of said at least one of the discrete structures
is less than 50 microns.

2. The x-ray target of claim 1, in which
the plurality of discrete structures are embedded into the surface of the substrate.

3. The x-ray target of claim 1, in which
the surface of the substrate is a planar surface.

4. The x-ray target of claim 1, in which
the surface of the substrate comprises a predetermined non-planar topography.

5. The x-ray target of claim 4, in which
the topography comprises at least one step.

6. The x-ray target of claim 1, in which
at least one of the plurality of discrete structures
is positioned within 1 mm from an edge of the substrate.

7. The x-ray target of claim 1, in which
the plurality of discrete structures are arranged in a periodic pattern.

8. The x-ray target of claim 1, in which
the plurality of discrete structures are arranged in a regular array.

9. The x-ray target of claim 1, in which
the plurality of discrete structures are arranged in a linear array.

10. The x-ray target of claim 1, in which
the plurality of discrete structures are fabricated to have similar shapes.

11. The x-ray target of claim 10, in which
the similar shapes are selected from the group consisting of
regular prisms, right rectangular prisms, cubes, triangular prisms, trapezoidal prisms, pyramids, tetrahedra, cylinders, spheres, ovoids, and barrel-shapes.

12. The x-ray target of claim 1, further comprising:
a third electrically conducting material
in electrical contact with the discrete structures.

13. The x-ray target of claim 1, further comprising:
an overcoat comprising a fourth thermally conducting material.

14. The x-ray target of claim 1, in which
the first selected material is selected from the group consisting of
beryllium, diamond, graphite, silicon, boron nitride, silicon carbide, sapphire and diamond-like carbon.

15. The x-ray target of claim 1, in which
the second material is selected from the group consisting of:
aluminum, titanium, vanadium, chromium, manganese, iron, cobalt, nickel, copper, gallium, zinc, yttrium, zirconium, molybdenum, niobium, ruthenium, rhodium, palladium, silver, tin, iridium, tantalum, tungsten, indium, cesium, barium, gold, platinum, lead and combinations and alloys thereof.

16. The x-ray target of claim 12, in which
the third material is selected from the group consisting of:
beryllium, aluminum, chromium, titanium, silver, gold, copper and carbon.

17. The x-ray target of claim 16, in which
the form of carbon is selected from the group consisting of graphite and carbon nanotubes.

18. The x-ray target of claim 13, in which
the fourth material is selected from the group consisting of:
diamond, diamond-like carbon, beryllium, silicon carbide, chromium, molybdenum, rhodium and palladium.

19. The x-ray target of claim 1, in which
the substrate additionally comprises at least one cooling channel
designed for the flow of a cooling fluid through the substrate.

20. The x-ray target of claim 1, in which
the substrate is mounted onto an additional heat sink.

21. The x-ray target of claim 20, in which
the additional heat sink comprises a thermoelectric cooler.

22. A method for manufacturing an x-ray target, comprising:
patterning a substrate comprising a first selected material;
depositing a second material selected for its x-ray generation properties
into portions of the patterned substrate
such that a plurality of discrete structures
are created that are in thermal contact with the substrate; and
such that at least one of the discrete structures
has a thickness of less than 10 microns, and
has each lateral dimension be less than 50 microns.

23. The method of claim 22, in which the step of patterning the substrate comprises:
attaching a pre-patterned layer to the substrate; and
etching the substrate.

24. The method of claim 23, in which
the step of etching the substrate comprises
using a reactive ion etch.

25. The method of claim 22, in which the step of patterning the substrate comprises:
coating the substrate with a resist;
patterning the resist using a lithographic process;
etching the substrate; and
removing the resist.

26. The method of claim 25, in which
the step of etching the substrate comprises
using a reactive ion etch.

27. The method of claim 22, in which the step of patterning the substrate comprises:
coating the substrate with a hard mask material,
coating the substrate with a resist;
patterning the resist using a lithographic process;
etching the hard mask;
removing the resist; and
etching the substrate.

28. The method of claim 27, in which
the step of etching the substrate comprises
using a reactive ion etch.

29. The method of claim 22, additionally comprising:
depositing an adhesion layer onto the patterned substrate
before the deposition of the second material.

30. The method of claim 22, additionally comprising:
polishing the second material after it has been deposited
to remove excess material.

31. The method of claim 22, additionally comprising:
depositing a third layer of conducting material
onto the patterned substrate with discrete structures.

32. The method of claim 31, additionally comprising:
creating a fourth layer of thermally conducting material
on the third layer of conducting material.

33. The method of claim 22, in which
the first selected material is selected from the group consisting of
beryllium, diamond, graphite, silicon, boron nitride, silicon carbide, sapphire and diamond-like carbon.

34. The method of claim 22, in which
the second material is selected from the group consisting of:
aluminum, titanium, vanadium, chromium, manganese, iron, cobalt, nickel, copper, gallium, zinc, yttrium, zirconium, molybdenum, niobium, ruthenium, rhenium, rhodium, palladium, silver, tin, iridium, tantalum, tungsten, indium, cesium, barium, gold, platinum, lead and combinations and alloys thereof.

35. The method of claim 31, in which
the third material is selected from the group consisting of:
beryllium, aluminum, chromium, titanium, silver, gold, copper and carbon.

36. The x-ray target of claim 35, in which
the form of carbon is selected from the group
consisting of graphite and carbon nanotubes.

37. The method of claim 32, in which
the fourth material is selected from the group consisting of:
diamond, diamond-like carbon, beryllium, silicon carbide, chromium, molybdenum, rhodium and palladium.

38. The method of claim 22, additionally comprising:
creating a cooling channel in the substrate.

39. The method of claim 22, additionally comprising:
mounting the substrate on a heat sink.

40. The method of claim 39, in which:
the heat sink comprises a thermoelectric cooler.

41. An x-ray target, comprising:
a substrate comprising a first selected material;
one or more discrete structures embedded in the substrate;
a third electrically conducting material
in electrical contact with one or more of the discrete structures; and
an overcoat comprising a fourth thermally conducting material;
in which each of the one or more discrete structures
comprises a second material selected for its x-ray generation properties; and
in which each of the one or more discrete structures
is in thermal contact with the substrate; and
in which at least one of the discrete structures
has a thickness of less than 10 microns and
lateral dimensions less than 50 microns.

42. The x-ray target of claim 41, in which
the first selected material comprises diamond;
the second selected material is selected from the group consisting of
copper, molybdenum and tungsten;
the third selected material comprises aluminum; and
the fourth thermally conducting material comprises diamond.
